(19) United States
(12) Patent Application Publication
(10) Pub. No.: US 2025/0113714 A1
(43) Pub. Date: Apr. 3, 2025

(54) DISPLAY SUBSTRATE AND MANUFACTURING METHOD THEREFOR, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Weishu WEN, Beijing (CN); Xiangyi LI, Beijing (CN); Runxin ZHANG, Beijing (CN); Hongtao WENG, Beijing (CN); Rui WANG, Beijing (CN); Yifan LIU, Beijing (CN)

(21) Appl. No.: 18/834,618

(22) PCT Filed: Oct. 7, 2023
(86) PCT No.: PCT/CN2023/123204

§ 371 Date: Jul. 30, 2024

(30) Foreign Application Priority Data
Oct. 20, 2022 (CN) 202211285974.X

(51) Int. Cl. H10K 59/131; H10K 59/12; H10K 59/121; H10K 59/35

(52) U.S. Cl. CPC H10K 59/131; H10K 59/1201; H10K 59/1213; H10K 59/35

(57) ABSTRACT

Disclosed is a display substrate including a display region which includes multiple pixel columns and multiple data signal lines, and a binding region which includes multiple detection units; the multiple pixel columns include first pixel columns and second pixel columns, the multiple data signal lines include first data signal lines which are electrically connected with multiple sub-pixels in the first pixel columns, and second data signal lines which are electrically connected with multiple sub-pixels in the second pixel columns; each detection unit include a first switch unit, a second switch unit, a third switch unit, a first transmission line and a second transmission line, the first switch unit is connected to the corresponding first data signal line by means of the first transmission line, and the second switch unit and the third switch unit are connected to the corresponding second data signal line by means of the second transmission line.

### CROSS-REFERENCE TO RELATED APPLICATIONS

The present application is a U.S. National Phase Entry of International Application No. PCT/CN2023/123204 having an international filing date of Oct. 7, 2023, which claims priority to Chinese Patent Application No. 202211285974.X, filed to the CNIPA on Oct. 20, 2022, the contents of the above-identified applications should be construed as being incorporated herein by reference.

### TECHNICAL FIELD

The present disclosure relates to, but is not limited to, the field of display technologies, and in particular to a display substrate, a preparation method therefor, and a display apparatus.

### BACKGROUND

An Organic Light Emitting Diode (OLED for short) and a Quantum dot Light Emitting Diode (QLED for short) are active light emitting display devices and have advantages such as self-luminescence, wide viewing angle, high contrast ratio, low power consumption, and a very high response speed. With continuous development of display technologies, a display apparatus in which an OLED or a QLED is used as a light emitting device and a Thin Film Transistor (TFT) is used for signal control has become a mainstream product in the field of display at present.

### SUMMARY

The following is a summary of subject matters described herein in detail. This summary is not intended to limit the protection scope of claims.

In one aspect, an exemplary embodiment of the present disclosure provides a display substrate, including a display region and a bonding region located on a side of the display region, wherein the display region at least includes a plurality of sub-pixels constituting a plurality of pixel columns and a plurality of data signal lines, and the bonding region at least includes a cell test circuit; the plurality of pixel columns at least include a first pixel column and a second pixel column, the first pixel column includes a plurality of first sub-pixels emitting light of a first color, and the second pixel column includes a plurality of second sub-pixels emitting light of a second color and a plurality of third sub-pixels emitting light of a third color; the plurality of data signal lines at least include a first data signal line and a second data signal line, the first data signal line is electrically connected with the plurality of first sub-pixels in the first pixel column, and the second data signal line is electrically connected with the plurality of second sub-pixels and the plurality of third sub-pixels in the second pixel column; the cell test circuit includes a plurality of test units, at least one test unit includes a first switching unit, a second switching unit, a third switching unit, a first transmission line and a second transmission line, wherein the first switching unit is connected with the first data signal line through the first transmission line, and the second switching unit and the third switching unit are connected with the second data signal line through the second transmission line; the second switching unit and the third switching unit are disposed at a side of the first switching unit away from the display region.

In an exemplary implementation, an extension length of the first transmission line is less than an extension length of the second transmission line in the bonding region.

In an exemplary implementation, one of the plurality of first sub-pixels includes a green sub-pixel emitting green light, one of the plurality of second sub-pixels includes a blue sub-pixel emitting blue light, and one of the plurality of third sub-pixels includes a red sub-pixel emitting red light.

In an exemplary implementation, the cell test circuit further includes a first control line and a first test line; the first control line is connected with a control terminal of the first switching unit, the first test line is connected with an input terminal of the first switching unit, an output terminal of the first switching unit is connected with the first transmission line, and the first switching unit is configured to send a signal transmitted by the first test line to the first data signal line through the first transmission line under control of the first control line.

In an exemplary implementation, the first switching unit includes at least one first transistor, the first control line is connected with a gate electrode of the first transistor, the first test line is connected with a first electrode of the first transistor, and a second electrode of the first transistor is connected with the first transmission line.

In an exemplary implementation, the first transmission line is disposed at a side of the gate electrode of the first transistor close to the display region, the first test line is disposed at a side of the gate electrode of the first transistor away from the display region, and the first control line is disposed at a side of the first test line away from the display region.

In an exemplary implementation, the first switching unit further includes a first gate connection line, a first end of the first gate connection line is connected with the gate electrode of the first transistor, and a second end of the first gate connection line, after extending along a direction away from the display region, is connected with the first control line through a via.

In an exemplary implementation, the first switching unit further includes a first connection electrode, a first end of the first connection electrode is connected with the first electrode of the first transistor through a via, and a second end of the first connection electrode is connected with the first transmission line through a via.

In an exemplary implementation, the cell test circuit further includes a second control line, a third control line, a second test line, and a third test line; the second control line is respectively connected with control terminals of second switching units in odd-numbered test units and control terminals of third switching units in even-numbered test units, and the third control line is respectively connected with control terminals of third switching units in the odd-numbered test units and control terminals of second switching units in the even-numbered test units; the second test line is connected with an input terminal of the second switching unit, and the third test line is connected with an input terminal of the third switching unit; an output terminal of the second switching unit is connected with the second transmission line, and an output terminal of the third switching unit is connected with the second transmission line; the second switching unit is configured to transmit a signal transmitted by the second test line to the second data signal line through the second transmission line under control of the second control line and the third control line, and the third switching unit is configured to transmit a signal transmitted by the third test line to the second data signal line through the second transmission line under control of the second control line and the third control line.

In an exemplary implementation, the second switching unit includes at least one second transistor and at least one third transistor, and the third switching unit includes at least one fourth transistor and at least one fifth transistor; the second control line is connected with gate electrodes of second transistors and gate electrodes of third transistors in the odd-numbered test units, and gate electrodes of fourth transistors and gate electrodes of fifth transistors in the even-numbered test units, respectively; the third control line is connected with gate electrodes of fourth transistors and gate electrodes of fifth transistors in the odd-numbered test units, and gate electrodes of second transistors and gate electrodes of third transistors in the even-numbered test units, respectively; the second test line is connected with a first electrode of the second transistor and a first electrode of the third transistor, respectively, and the third test line is connected with a first electrode of the fourth transistor and a first electrode of the fifth transistor, respectively; and a second electrode of the second transistor, a second electrode of the third transistor, a second electrode of the fourth transistor, and a second electrode of the fifth transistor are connected with the second transmission line.

In an exemplary implementation, the third transistor is disposed at a side of the second transistor away from the display region, the fourth transistor is disposed at a side of the third transistor away from the display region, and the fifth transistor is disposed at a side of the fourth transistor away from the display region.

In an exemplary implementation, the second test line includes a first sub-line and a second sub-line; the first sub-line is disposed at a side of the second transistor close to the display region, and is connected with the first electrode of the second transistor; the second sub-line is disposed at a side of the third transistor away from the display region and is connected with the first electrode of the third transistor; and the second control line is disposed at a side of the second sub-line away from the display region.

In an exemplary implementation, the second switching unit further includes a second gate connection line, a first end of the second gate connection line is connected with a gate electrode of the second transistor and a gate electrode of the third transistor, respectively, and a second end of the second gate connection line, after extending along a direction away from the display region, is connected with the second control line or the third control line through a via.

In an exemplary implementation, the second switching unit further includes a second connection electrode respectively connected with the second electrode of the second transistor, the second electrode of the third transistor, and the second transmission line through a via.

In an exemplary implementation, the second switching unit further includes a second connection block, the second connection block is connected with the second transmission line, the second connection electrode is connected with the second connection block through a via, and the second connection block and the second transmission line are disposed in a same layer and are of an interconnected integral structure.

In an exemplary implementation, the third test line includes a third sub-line and a fourth sub-line; the third sub-line is disposed at a side of the fourth transistor close to the display region, and is connected with the first electrode of the fourth transistor; the fourth sub-line is disposed at a side of the fifth transistor away from the display region and is connected with the first electrode of the fifth transistor; and the third control line is disposed at a side of the third sub-line close to the display region.

In an exemplary implementation, the third switching unit further includes a third gate connection line, a first end of the third gate connection line is connected with a gate electrode of the fourth transistor and a gate electrode of the fifth transistor, respectively, and a second end of the third gate connection line, after extending along a direction close to the display region, is connected with the second control line or the third control line through a via.

In an exemplary implementation, the third switching unit further includes a third connection electrode respectively connected with the second electrode of the fourth transistor, the second electrode of the fifth transistor, and the second transmission line through a via.

In an exemplary implementation, the third switching unit further includes a third connection block, the third connection block is connected with the second transmission line, the third connection electrode is connected with the third connection block through a via, and the third connection block and the second transmission line are disposed in a same layer and are of an interconnected integral structure.

In another aspect, an exemplary embodiment of the present disclosure further provides a display apparatus, which includes any one of the aforementioned display substrate described in.

In yet another aspect, an exemplary embodiment of the present disclosure further provides a preparation method of a display substrate, wherein the display substrate includes a display region and a bonding region located on a side of the display region, wherein the display region at least includes a plurality of sub-pixels constituting a plurality of pixel columns and a plurality of data signal lines, and the bonding region at least includes a cell test circuit; the plurality of pixel columns at least include a first pixel column and a second pixel column, the first pixel column includes a plurality of first sub-pixels emitting light of a first color, and the second pixel column includes a plurality of second sub-pixels emitting light of a second color and a plurality of third sub-pixels emitting light of a third color; the plurality of data signal lines at least include a first data signal line and a second data signal line, the first data signal line is electrically connected with the plurality of first sub-pixels in the first pixel column, and the second data signal line is electrically connected with the plurality of second sub-pixels and the plurality of third sub-pixels in the second pixel column; the preparation method includes: forming the cell test circuit in the bonding region, the cell test circuit includes a plurality of test units, at least one test unit includes a first switching unit, a second switching unit, a third switching unit, a first transmission line and a second transmission line, wherein the first switching unit is connected with the first data signal line through the first transmission line, the second switching unit and the third switching unit are connected with the second data signal line through the second transmission line, and the second switching unit and the third switching unit are disposed at a side of the first switching unit away from the display region.

Other aspects may be comprehended upon reading and understanding drawings and detailed description.

### BRIEF DESCRIPTION OF DRAWINGS

Accompanying drawings are used for providing further understanding of technical solutions of the present disclosure, constitute a portion of the specification, and are used for explaining the technical solutions of the present disclosure together with embodiments of the present disclosure, but do not constitute limitations on the technical solutions of the present disclosure. Shapes and sizes of various components in the drawings do not reflect actual scales, but are only intended to schematically illustrate contents of the present disclosure.

FIG. 1 is a schematic diagram of a structure of a display apparatus.

FIG. 2 is a schematic diagram of a structure of a display substrate.

FIG. 3 is a schematic diagram of a planar structure of a display region in a display substrate.

FIG. 4 is a schematic diagram of a sectional structure of a display region in a display substrate.

FIG. 5 is an equivalent circuit diagram of a pixel drive circuit.

FIG. 6 is a schematic diagram of a planar structure of a bonding region in a display substrate.

FIG. 7 is a schematic diagram of CT test on a display substrate.

FIG. 8 is an equivalent circuit diagram of a cell test circuit according to an exemplary embodiment of the present disclosure.

FIG. 9 is a schematic diagram of a structure of a display substrate according to an exemplary embodiment of the present disclosure.

FIG. 10 is a schematic diagram obtained after a pattern of a semiconductor layer is formed according to an embodiment of the present disclosure.

FIG. 11 is a schematic diagram obtained after a pattern of a first conductive layer is formed according to an embodiment of the present disclosure.

FIG. 12 is a schematic diagram obtained after a pattern of a second conductive layer is formed according to an embodiment of the present disclosure.

FIG. 13 is a schematic diagram obtained after a pattern of a fourth insulating layer is formed according to an embodiment of the present disclosure.

FIG. 14 is a schematic diagram obtained after a pattern of a third conductive layer is formed according to an embodiment of the present disclosure.

Reference signs are described as follows.

| | | |
|---|---|---|
| 10-test unit; | 11-first active layer; | 12-second active layer; |
| 13-third active layer; | 14-fourth active layer; | 15-fifth active layer; |
| 20-control line; | 21-first gate electrode; | 22-second gate electrode; |
| 23-third gate electrode; | 24-fourth gate electrode; | 25-fifth gate electrode; |
| 30-test line; | 61-first gate connection line; | 62-second gate connection |
| | | line; |
| 63-third gate connection line; | 71-first transmission line; | 72-second transmission line; |
| 81-first connection block; | 82-second connection block; | 83-third connection block; |
| 91-first connection electrode; | 92-second connection electrode; | 93-third connection electrode; |
| 100-display region; | 101-base substrate; | 102-drive circuit layer; |
| 103-light emitting structure | 104-encapsulation structure | 200-bonding region; |
| layer; | layer; | |
| 110- first control line; | 120- second control line; | 130-third control line; |
| 210-first test line; | 220-second test line; | 220-1-first sub-line; |
| 220-2-second sub-line; | 230-third test line; | 230-1-third sub-line; |
| 230-2-fourth sub-line; | 300-bezel region. | |

### DETAILED DESCRIPTION

To make the objectives, technical solutions, and advantages of the present disclosure clearer, the embodiments of the present disclosure will be described in detail below with reference to the accompany drawings. It is to be noted that implementations may be implemented in multiple different forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements with reference to the drawings, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, it may be a fixed connection, a detachable connection, or an integral connection; it may be a mechanical connection or a connection; it may be a direct connection, an indirect connection through a middleware, or an internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, a “connection” includes a case where composition elements are connected together through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulating film” may be replaced with an “insulating layer” sometimes.

A triangle, rectangle, trapezoid, pentagon, or hexagon, etc. in this specification is not strictly defined, and it may be an approximate triangle, rectangle, trapezoid, pentagon, or hexagon, etc. There may be some small deformations caused by tolerance, and there may be chamfer, arc edge, deformation, etc.

In the present disclosure, “about” refers to that a boundary is not defined so strictly and numerical values within a range of process and measurement errors are allowed.

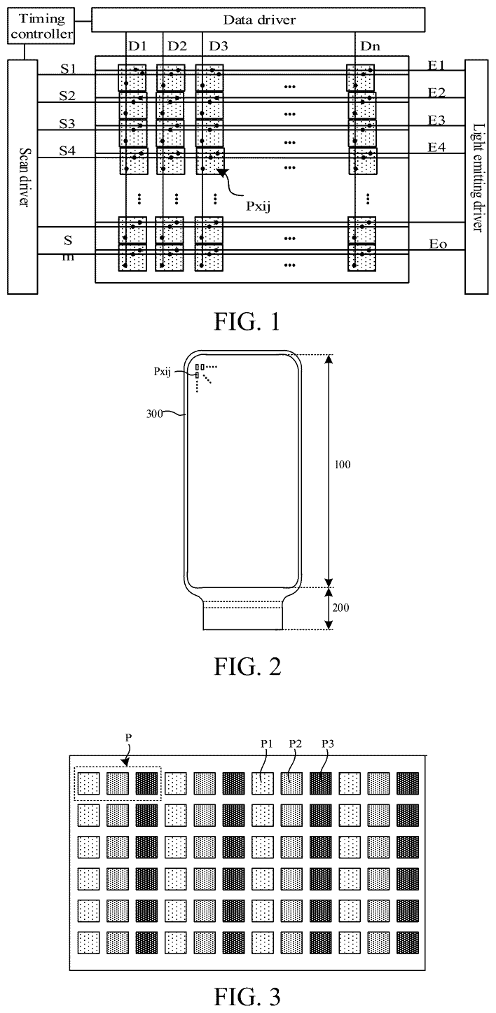

FIG. 1 is a schematic diagram of a structure of a display apparatus. As shown in FIG. 1, the display apparatus may include a timing controller, a data driver, a scan driver, a light emitting driver, and a pixel array. The timing controller is connected with the data driver, the scan driver, and the light emitting driver, respectively, the data driver is connected with a plurality of data signal lines (D1 to Dn) respectively, the scan driver is connected with a plurality of scan signal lines (S1 to Sm) respectively, and the light emitting driver is connected with a plurality of light emitting signal lines (E1 to Eo) respectively. The pixel array may include a plurality of sub-pixels Pxij, wherein i and j may be natural numbers. At least one sub-pixel Pxij may include a circuit unit and a light emitting device connected with the circuit unit, wherein the circuit unit may at least include a pixel drive circuit, and the pixel drive circuit is connected with a scan signal line, a light emitting signal line, and a data signal line, respectively. In an exemplary implementation, the timing controller may provide the data driver with a gray scale value and a control signal which are suitable for the specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate data voltages to be provided to the data signal lines D1, D2, D3, . . . , and Dn using the grayscale value and the control signal that are received from the timing controller. For example, the data driver may sample the gray scale value using the clock signal and apply a data voltage corresponding to the gray scale value to the data signal lines D1 to Dn by taking a pixel row as a unit, wherein n may be a natural number. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and generate a scan signal in a manner of sequentially transmitting scan start signals provided in a form of an on-level pulse to a next-stage circuit under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number.

FIG. 2 is a schematic diagram of a structure of a display substrate. As shown in FIG. 2, the display substrate may include a display region 100, a bonding region 200 located on a side of the display region 100, and a bezel region 300 located on another side of the display region 100. In an exemplary implementation, the display region 100 may be a plat region, including a plurality of sub-pixels Pxij that constitute a pixel array, wherein the plurality of sub-pixels Pxij are configured to display a dynamic picture or a static image, and the display region 100 may be referred to as an Active Area (AA). In an exemplary implementation, the display substrate may be a flexible substrate, so that the display substrate may be deformable, for example, be curled, bent, folded, or rolled.

In an exemplary implementation, the bonding region 200 may include a fan-out region, a bending region, a cell test circuit region, a drive chip region, and a bonding pin region sequentially disposed along a direction away from the display region, wherein the fan-out region is connected to the display region 100 and may at least include data transmission lines, and a plurality of data transmission lines are configured to connect a data signal line of the display region in a fan-out trace manner. The bending region is connected to the fan-out region and may at least include a composite insulating layer provided with a groove, and is configured to enable the bonding region to be bent to a back of the display region. The cell test circuit region may at least include a cell test circuit, and the drive chip region may at least include an Integrated Circuit (IC for short) configured to be connected with the plurality of data transmission lines. The bonding pin region may at least include multiple pins (PIN for short) which are configured to be bonded to and connected to an external Flexible Printed Circuit (FPC for short).

In an exemplary implementation, the bezel region 300 may include a circuit region, a power supply line region, a crack dam region, and a cutting region which are sequentially disposed along a direction away from the display region 100. The circuit region is connected to the display region 100 and may at least include multiple cascaded gate drive circuits, and the gate drive circuits are connected to a plurality of scan lines of pixel drive circuits in the display region 100. The power supply line region is connected to the circuit region and may at least include a bezel power supply lead, wherein the bezel power supply lead extends along a direction parallel to an edge of the display region and is connected with a cathode in the display region 100. The crack dam region is connected to the power supply line region and may at least include a plurality of cracks disposed on the composite insulating layer. The cutting region is connected to the crack dam region and may at least include a cutting groove disposed on the composite insulating layer, wherein the cutting groove is configured for respectively cutting along the cutting groove by a cutting device after all film layers of the display substrate are prepared.

In an exemplary implementation, the fan-out region in the bonding region 200 and the power supply line region in the bezel region 300 may be provided with a first isolation dam and a second isolation dam, wherein the first isolation dam and the second isolation dam may extend along the direction parallel to the edge of the display region, forming an annular structure surrounding the display region 100, and the edge of the display region is an edge on one side of the display region, the bonding region, or the bezel region.

FIG. 3 is a schematic diagram of a planar structure of a display region in a display substrate. As shown in FIG. 3, the display region may include a plurality of pixel units P arranged in an array. At least one pixel unit P may include a sub-pixel P1 emitting light of a first color, a second sub-pixel P2 emitting light of a second color, and a third sub-pixel P3 emitting light of a third color. Each sub-pixel may include a circuit unit and a light emitting unit, wherein the circuit unit may at least include a pixel drive circuit which is connected with a scan signal line, a data signal line, and a light emitting signal line respectively, and the pixel drive circuit is configured to receive a data voltage transmitted by the data signal line and output a corresponding current to the light emitting device under control of the scan signal line and the light emitting signal line. A light emitting unit may at least include a light emitting device. The light emitting device is respectively connected with the pixel drive circuit of the sub-pixel where the light emitting device is located. The light emitting device is configured to emit light with a corresponding brightness in response to a current output by the pixel drive circuit of the sub-pixel where the light emitting device is located.

In an exemplary implementation, the first sub-pixel P1 may be a green (G) sub-pixel emitting green light, the second sub-pixel P2 may be a blue (B) sub-pixel emitting blue light, and the third sub-pixel P3 may be a red (R) sub-pixel emitting red light. In an exemplary implementation, a sub-pixel may be in a shape of a rectangle, a rhombus, a pentagon, or a hexagon. Three sub-pixels may be arranged in a manner to stand side by side horizontally, in a manner to stand side by side vertically, or in a delta-shaped arrangement, etc., which is not limited here in the present disclosure.

In an exemplary implementation, a pixel unit may include four sub-pixels, and the four sub-pixels may be arranged in a manner to stand side by side horizontally, in a manner to stand side by side vertically, or in a manner of a square, which is not limited here in the present disclosure.

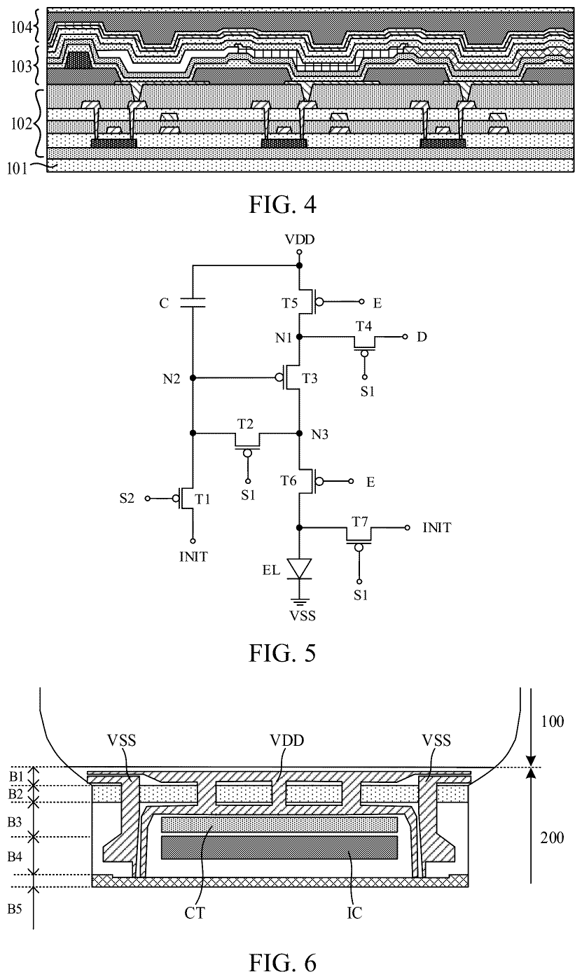

FIG. 4 is a schematic diagram of a sectional structure of a display region in a display substrate, illustrating a structure of three sub-pixels in the display region. As shown in FIG. 4, on a plane perpendicular to the display substrate, the display region may include a drive circuit layer 102 provided on a base substrate 101, a light emitting structure layer 103 provided on a side of the drive circuit layer 102 away from the base substrate 101, and an encapsulation structure layer 104 provided on a side of the light emitting structure layer 103 away from the base substrate 101. In some possible implementations, the display substrate may include another film layer, such as a touch structure layer, which is not limited here in the present disclosure.

In an exemplary implementation, the base substrate 101 may be a flexible base substrate, or may be a rigid base substrate. The drive circuit layer 102 may include a plurality of circuit units, a circuit unit may at least include a pixel drive circuit, and the pixel drive circuit may include a plurality of transistors and a storage capacitor. In FIG. 4, only one pixel drive circuit including one transistor and one storage capacitor is taken as an example. The light emitting structure layer 103 may include a plurality of light emitting units, a light emitting unit may at least include a light emitting device, and the light emitting device may include an anode, an organic emitting layer, and a cathode. The anode is connected to a pixel drive circuit. The organic emitting layer is connected to the anode. The cathode is connected to the organic emitting layer. The organic emitting layer emits light of a corresponding color under driving of the anode and the cathode. The encapsulation layer 104 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is arranged between the first encapsulation layer and the third encapsulation layer to form a laminated structure of inorganic material/organic material/inorganic material and ensure that external moisture cannot enter the light emitting structure layer 103.

FIG. 5 is an equivalent circuit diagram of a pixel drive circuit. In an exemplary implementation, the pixel drive circuit may have a structure of 3T1C, 4T1C, 5T1C, 5T2C, 6T1C, 7T1C, or 8T1C. As shown in FIG. 5, the pixel drive circuit may include seven transistors (a first transistor T1 to a seventh transistor T7), and one storage capacitor C. The pixel drive circuit is connected to six signal lines (a data signal line D, a first scan signal line S1, a second scan signal line S2, a light emitting signal line E, an initial signal line INIT, and a first power supply line VDD) respectively.

In an exemplary implementation, the pixel drive circuit may include a first node N1, a second node N2, and a third node N3. Herein, the first node N1 is respectively connected with a first electrode of the third transistor T3, a second electrode of the fourth transistor T4, and a second electrode of the fifth transistor T5, the second node N2 is respectively connected with a second electrode of the first transistor, a first electrode of the second transistor T2, a gate electrode of the third transistor T3, and a first end of the storage capacitor C, and the third node N3 is respectively connected with a second electrode of the second transistor T2, a second electrode of the third transistor T3, and a first electrode of the sixth transistor T6.

In an exemplary implementation, the first end of the storage capacitor C is connected to the second node N2, and a second end of the storage capacitor C is connected to the first power supply line VDD.

In an exemplary implementation, a gate electrode of the first transistor T1 is connected to the second scan signal line S2, a first electrode of the first transistor T1 is connected to the initial signal line INIT, and the second electrode of the first transistor is connected to the second node N2. When a scan signal with an on-level is applied to the second scan signal line S2, the first transistor T1 transmits a first initialization voltage to the gate electrode of the third transistor T3 so as to initialize a charge amount of the gate electrode of the third transistor T3.

In an exemplary implementation, a gate electrode of the second transistor T2 is connected to the first scan signal line S1, the first electrode of the second transistor T2 is connected to the second node N2, and the second electrode of the second transistor T2 is connected to the third node N3. When a scan signal with an on-level is applied to the first scan signal line S1, the second transistor T2 enables the gate electrode of the third transistor T3 to be connected with the second electrode of the third transistor T3.

The gate electrode of the third transistor T3 is connected to the second node N2, namely the gate electrode of the third transistor T3 is connected to the first end of the storage capacitor C, the first electrode of the third transistor T3 is connected to the first node N1, and the second electrode of the third transistor T3 is connected to the third node N3. The third transistor T3 may be referred to as a drive transistor, and the third transistor T3 determines an amount of a drive current flowing between the first power supply line VDD and the second power supply line VSS according to a potential difference between the gate electrode and the first electrode of the third transistor T3.

A gate electrode of the fourth transistor T4 is connected with the first scan signal line S1, a first electrode of the fourth transistor T4 is connected with the data signal line D, and a second electrode of the fourth transistor T4 is connected with the first node N1. The fourth transistor T4 may be referred to as a switching transistor, a scan transistor, etc., and the fourth transistor T4 enables a data voltage of the data signal line D to be input into the pixel drive circuit when a scan signal with an on-level is applied to the first scan signal line S1.

A gate electrode of the fifth transistor T5 is connected with the light emitting signal line E, a first electrode of the fifth transistor T5 is connected with the first power supply line VDD, and a second electrode of the fifth transistor T5 is connected with the first node N1. A gate electrode of the sixth transistor T6 is connected with the light emitting signal line E, a first electrode of the sixth transistor T6 is connected with the third node N3, and a second electrode of the sixth transistor T6 is connected with a first electrode of a light emitting device. The fifth transistor T5 and the sixth transistor T6 may be referred to as light emitting transistors. When a light emitting signal with an on-level is applied to the light emitting signal line E, the fifth transistor T5 and the sixth transistor T6 enable the light emitting device to emit light by forming a drive current path between the first power supply line VDD and the second power supply line VSS.

A gate electrode of the seventh transistor T7 is connected to the first scan signal line S1, a first electrode of the seventh transistor T7 is connected to the initial signal line INIT, and a second electrode of the seventh transistor T7 is connected to the first electrode of the light emitting device. When a scan signal with an on-level is applied to the first scan signal line S1, the seventh transistor T7 transmits a second initial voltage to the first electrode of the light emitting device so as to initialize a charge amount accumulated in the first electrode of the light emitting device or release a charge amount accumulated in the first electrode of the light emitting device.

In an exemplary implementation, the light emitting device EL may be an OLED including a first electrode (anode), an organic light emitting layer, and a second electrode (cathode), which are stacked, or may be a QLED including a first electrode (anode), a quantum dot light emitting layer, and a second electrode (cathode), which are stacked.

In an exemplary implementation, a second electrode of the light emitting device EL is connected to the second power supply line VSS, a signal of the second power supply line VSS is a low-level signal continuously provided, and a signal of the first power supply line VDD is a high-level signal continuously provided.

In an exemplary implementation, the first transistor T1 to the seventh transistor T7 may be P-type transistors, or may be N-type transistors. Use of a same type of transistors in a pixel drive circuit may simplify a process flow, reduce a process difficulty of a display panel, and improve a product yield. In some possible implementations, the first transistor T1 to the seventh transistor T7 may include a P-type transistor and an N-type transistor.

In an exemplary implementation, for the first transistor T1 to the seventh transistor T7, low temperature poly silicon thin film transistors may be used, or oxide thin film transistors may be used, or both a low temperature poly silicon thin film transistor and an oxide thin film transistor may be used. An active layer of a low temperature poly silicon thin film transistor is made of Low Temperature Poly silicon (LTPS for short), and an active layer of an oxide thin film transistor is made of an oxide semiconductor (Oxide). A Low temperature poly silicon thin film transistor has advantages such as a high migration rate and fast charging, and an oxide thin film transistor has advantages such as a low leakage current. The low temperature poly silicon thin film transistor and the oxide thin film transistor are integrated on one display substrate to form a Low Temperature Polycrystalline Oxide (LTPO for short) display substrate, so that advantages of both the low temperature poly silicon thin film transistor and the oxide thin film transistor may be utilized, low-frequency drive may be achieved, power consumption may be decreased, and display quality may be improved.

In an exemplary implementation, taking a case that the seven transistors in the pixel drive circuit shown in FIG. 5 are all P-type transistors as an example, a working process of the pixel drive circuit may include following stages.

In a first stage (which may be referred to as a reset stage), a signal of the second scan signal line S2 is a low-level signal, and signals of the first scan signal line S1 and the light emitting signal line E are high-level signals. The signal of the second scan signal line S2 is the low-level signal, so that the first transistor T1 is turned on, and a signal of the initial signal line INIT is provided to the second node N2 to initialize the storage capacitor C to clear an original data voltage in the storage capacitor. The signals of the first scan signal line S1 and the light emitting signal line E are the high-level signals, so that the second transistor T2, the fourth transistor T4, the fifth transistor T5, the sixth transistor T6, and the seventh transistor T7 are turned off. An OLED does not emit light in this stage.

In a second stage (which may be referred to as a data writing stage or a threshold compensation stage), a signal of the first scan signal line S1 is a low-level signal, signals of the second scan signal line S2 and the light emitting signal line E are high-level signals, and the data signal line D outputs a data voltage. In this stage, the first end of the storage capacitor C is at a low-level, so the third transistor T3 is turned on. The signal of the first scan signal line S1 is the low-level signal, so that the second transistor T2, the fourth transistor T4, and the seventh transistor T7 are turned on. The second transistor T2 and the fourth transistor T4 are turned on, so that the data voltage output by the data signal line D is provided to the second node N2 through the first node N1, the turned-on third transistor T3, the third node N3, and the turned-on second transistor T2, and the storage capacitor C is charged with a difference between the data voltage output by the data signal line D and a threshold voltage of the third transistor T3. A voltage at the second end (the second node N2) of the storage capacitor C is Vd−|Vth|, wherein Vd is the data voltage output by the data signal line D, and Vth is the threshold voltage of the third transistor T3. The seventh transistor T7 is turned on, so that an initialization voltage of the initial signal line INIT is provided to a first electrode of the OLED to initialize (reset) the first electrode of the OLED and clear a pre-stored voltage therein, thereby completing initialization and ensuring that the OLED does not emit light. A signal of the second scan signal line S2 is a high-level signal, so that the first transistor T1 is turned off. A signal of the light emitting signal line E is a high-level signal, so that the fifth transistor T5 and the sixth transistor T6 are turned off.

In a third stage (which may be referred to as a light emitting stage), a signal of the light emitting signal line E is a low-level signal, and signals of the first scan signal line S1 and the second scan signal line S2 are high-level signals. The signal of the light emitting signal line E is the low-level signal, so that the fifth transistor T5 and the sixth transistor T6 are turned on, and a power voltage output by the first power supply line VDD provides a drive voltage to the first electrode of the OLED through the turned-on fifth transistor T5, the third transistor T3, and the sixth transistor T6 to drive the OLED to emit light.

In a drive process of the pixel drive circuit, a drive current flowing through the third transistor T3 (drive transistor) is determined by a voltage difference between a gate electrode and the first electrode of the third transistor T3. Since the voltage of the second node N2 is Vd−|Vth|, the drive current of the third transistor T3 is as follows.

I=K*(Vgs−Vth)²=K*[(Vdd−Vd+|Vth|)−Vth]²=K*[Vdd−Vd]²

Herein, I is a drive current flowing through the third transistor T3, i.e., a drive current for driving the OLED, K is a constant, Vgs is the voltage difference between the gate electrode and the first electrode of the third transistor T3, Vth is the threshold voltage of the third transistor T3, Vd is the data voltage output by the data signal line D, and Vdd is the power voltage output by the first power supply line VDD.

FIG. 6 is a schematic diagram of a planar structure of a bonding region in a display substrate. As shown in FIG. 6, in an exemplary implementation, in a plane parallel to the display substrate, the bonding region 200 may be on a side of a display region 100, and the bonding region 200 may include a fan-out region B1, a bending region B2, a cell test circuit region B3, a drive chip region B4, and a bonding pin region B5 that are provided sequentially along a direction away from the display region 100. The first fan-out region B1 at least includes a first power supply line VDD, and a second power supply line VSS and a plurality of data transmission lines. The plurality of data transmission lines are configured to be connected with data signal lines of the display region 100, the first power supply line VDD configured to be connected with a high-level power supply line of the display region 100, and the second power supply line VSS configured to be connected with a low-level power supply line of the bezel region. The bending region B2 may include a composite insulating layer provided with a groove, wherein the groove is configured to allow the bonding region 200 to be bent to the back of the display region 100. The cell test circuit region B3 may be provided with a Cell Test circuit (CT for short) for test on the display substrate, and the cell test circuit CT may be connected with a corresponding signal line of the display region, and a test of the display substrate can be achieved. The drive chip region B4 may be provided with an integrated circuit IC, and the integrated circuit IC is connected to a data signal line of the display region through a data transmission line in the first fan-out region B1 and the integrated circuit IC is configured to generate a drive signal required for driving a sub-pixel, and to supply the drive signal to the data signal line of the display region. For example, the drive signal may be a data signal that drives luminance of the sub-pixel. The bonding pin region B5 may be provided with multiple PINs configured to be bonded to and connected to an external Flexible Printed Circuit (FPC). In an exemplary implementation, the bonding region may include other circuits and signal lines such as an anti-static circuit, a multiplexing circuit (MUX) or the like, which are not limited here in the present disclosure.

In an exemplary implementation, the preparation process of the display substrate requires a plurality of tests, and one important test is a picture test using a cell test circuit CT, also known as CT test. The CT test means that before the display substrate is bonded to a drive chip (IC) and a flexible circuit board (FPC) for inputting a display signal, a test signal is input to the display substrate to make its pixels present color, and a defect test device checks whether each pixel is in good condition to confirm whether the display substrate has defects.

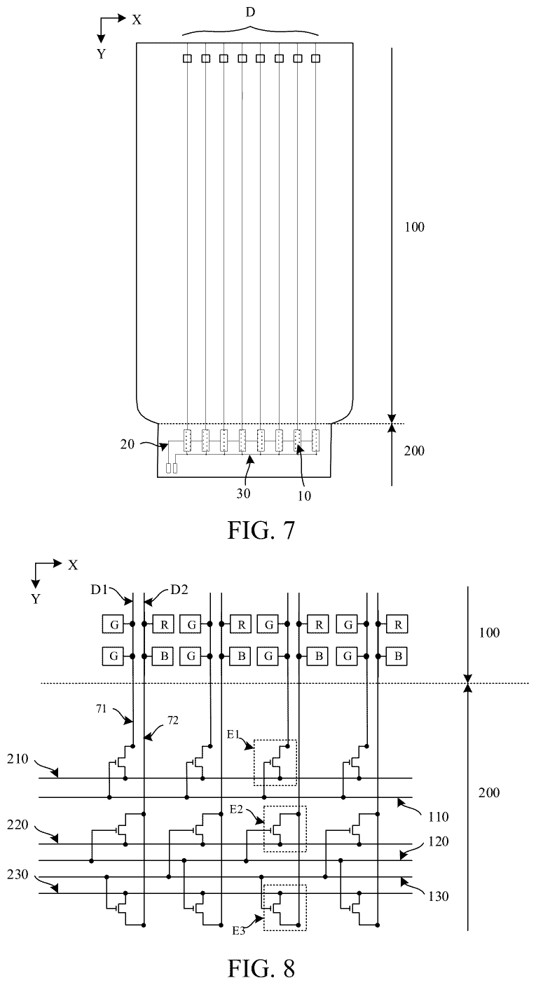

FIG. 7 is a schematic diagram of CT test on a display substrate. As shown in FIG. 7, the display substrate may include a display region 100 and a bonding region 200 located on a side of the display region 100. The display region 100 may include a plurality of sub-pixels constituting a plurality of pixel rows and a plurality of pixel columns, and a plurality of data signal lines D. A sub-pixel may include a circuit unit and a light emitting device, the circuit unit may at least include a pixel drive circuit, and the light emitting device may be connected to the pixel drive circuit of the corresponding circuit unit. The plurality of data signal lines D may extend along a second direction Y and are provided sequentially at set intervals along a first direction X. Each of the data signal lines D is electrically connected to pixel drive circuits of a plurality of sub-pixels in one pixel column, the second direction Y and the first direction X intersect with each other. In an exemplary implementation, the second direction Y may be a pixel column direction, the first direction X may be a pixel row direction, the second direction Y may be a pixel column direction, and the first direction X and the second direction Y may be perpendicular to each other.

In an exemplary implementation, the bonding region 200 may include a cell test circuit, the cell test circuit may at least include a plurality of test units 10, a control line 20 and a test line 30. The plurality of test units 10 may be provided sequentially at set intervals along the first direction X and positions of the plurality of test units 10 may be in one-to-one correspondence with positions of the plurality of data signal lines D in the display region 100. Each of the test units 10 may include a control terminal, an input terminal and an output terminal, one end of the control line 20 is connected correspondingly to a pin in a bonding pin region, and the other end of the control line 20 may be connected correspondingly to the control terminals of the plurality of test units 10, and the control line 20 is configured to control on or off of the plurality of test units 10. One end of the test line 30 is connected correspondingly to the pin of the bonding pin region, the other end of the test line 30 may be connected correspondingly to the input terminals of the plurality of test units 10, and the output terminals of the plurality of test units 10 may be connected correspondingly to the plurality of data signal lines D of the display region 100. The test units 10 are configured to output a signal output from the test line 30 to the data signal lines D of the display region 100 under control of the control line 20, so that a CT test of the display substrate is achieved.

In an exemplary implementation, a process of a CT test of the cell test circuit is as follows: before the display substrate is bonded to the Drive Chip (IC) and the Flexible Printed Circuit (FPC), an external device is connected to a pin in the bonding region, wherein the external device outputs a control signal and an test signal to the test circuit through the pin, the control signal controls a plurality of test units to be turned on, and the plurality of test units output the test signal to a plurality of data signal lines in the display region and perform a CT test for red sub-pixels, blue sub-pixels and green sub-pixels respectively.

With development of OLED display technologies, consumers have higher requirements for a display effect of a display product. An extremely narrow bezel or even borderless design has become a new trend in development of display products. Because a cell test circuit occupies a large area in a cell test circuit region, it is necessary to reduce a size of the cell test circuit for narrowing the bonding region.

An exemplary embodiment of the present disclosure provides a display substrate, including a display region and a bonding region located on a side of the display region, wherein the display region at least includes a plurality of sub-pixels constituting a plurality of pixel columns and a plurality of data signal lines, and the bonding region at least includes a cell test circuit; the plurality of pixel columns at least include a first pixel column and a second pixel column, the first pixel column includes a plurality of first sub-pixels emitting light of a first color, and the second pixel column includes a plurality of second sub-pixels emitting light of a second color and a plurality of third sub-pixels emitting light of a third color; the plurality of data signal lines at least include a first data signal line and a second data signal line, the first data signal line is electrically connected with the plurality of first sub-pixels in the first pixel column, and the second data signal line is electrically connected with the plurality of second sub-pixels and the plurality of third sub-pixels in the second pixel column; the cell test circuit includes a plurality of test units, at least one test unit includes a first switching unit, a second switching unit, a third switching unit, a first transmission line and a second transmission line, wherein the first switching unit is connected with the first data signal line through the first transmission line, and the second switching unit and the third switching unit are connected with the second data signal line through the second transmission line; the second switching unit and the third switching unit are disposed at a side of the first switching unit away from the display region.

In an exemplary implementation, an extension length of the first transmission line is less than an extension length of the second transmission line in the bonding region.

In an exemplary implementation, a first sub-pixel includes a green sub-pixel emitting green light, a second sub-pixel includes a blue sub-pixel emitting blue light, and a third sub-pixel includes a red sub-pixel emitting red light.

FIG. 8 is an equivalent circuit diagram of a cell test circuit according to an exemplary embodiment of the present disclosure. As shown in FIG. 8, the display region 100 may include a plurality of sub-pixels constituting a plurality of pixel rows and a plurality of pixel columns and a plurality of data signal lines, and the bonding region 200 may include a cell test circuit. The plurality of pixel columns may at least include a first pixel column (odd-numbered pixel columns) and a second pixel column (even-numbered pixel columns), the first pixel column may include a plurality of green (G) sub-pixels emitting green light, the second pixel column may include a plurality of blue (B) sub-pixels emitting blue light and a plurality of red (R) sub-pixels emitting red light, and the first pixel column and the second pixel column are alternately disposed along the first direction X. The plurality of data signal lines may at least include a first data signal line D1 and a second data signal line D2, the position of the first data signal line D1 corresponds to the position of the first pixel column, the first data signal line D1 is electrically connected with the plurality of G sub-pixels in the first pixel column, the position of the second data signal line D2 corresponds to the position of the second pixel column, the second data signal line D2 is electrically connected with the plurality of B sub-pixels and the plurality of R sub-pixels in the second pixel column, and the first data signal line D1 and the second data signal line D2 are alternately disposed along the first direction X. In the present disclosure, a data signal line being electrically connected with a plurality of sub-pixels in a pixel column refers to the data signal line being electrically connected with pixel drive circuits of the plurality of sub-pixels in the pixel column.

In an exemplary implementation, the cell test circuit may include a plurality of test units sequentially disposed along the first direction X, positions of the plurality of test units correspond to positions of the plurality of pixel columns, the plurality of test units may include a plurality of odd-numbered test units and a plurality of even-numbered test units, the plurality of odd-numbered test units and the plurality of even-numbered test units are disposed at intervals, an odd-numbered test unit is connected with a data signal line in an odd-numbered pixel column, and an even-numbered test unit is connected with a data signal line in an even-numbered pixel column.

In an exemplary implementation, at least one test unit may include a first switching unit E1, a second switching unit E2, a third switching unit E3, a first transmission line 71, and a second transmission line 72. A first end of the first transmission line 71 is connected with the first switching unit E1, and a second end of the first transmission line 71 is connected with the first data signal line D1 of the display region 100, that is, the first switching unit E1 is connected with the first data signal line D1 through the first transmission line 71. A first end of the second transmission line 72 is connected with the second switching unit E2 and the third switching unit E3, respectively, and a second end of the second transmission line 72 is connected with the second data signal line D2 of the display region 100, that is, the second switching unit E2 and the third switching unit E3 are connected with the second data signal line D2 through the second transmission line 72.

In an exemplary implementation, the second switching unit E2 and the third switching unit E3 may be disposed at a side of the first switching unit E1 away from the display region 100.

In an exemplary implementation, the second switching unit E2 may be disposed at a side of the first switching unit E1 away from the display region 100, and the third switching unit E3 may be disposed at a side of the second switching unit E2 away from the display region 100, that is, the first switching unit E1, the second switching unit E2, and the third switching unit E3 may be sequentially disposed in a direction away from the display region, and each switching unit may include a control terminal, an input terminal, and an output terminal.

In an exemplary implementation, since the distance between the first switching unit E1 and the display region is less than the distance between the second switching unit E2 and the display region, in the bonding region 200, the extension length of the first transmission line 71 extending in a direction close to the display region is less than the extension length of the second transmission line 72 extending in the direction close to the display region.

In an exemplary implementation, the cell test circuit may further include a plurality of signal lines, and the plurality of signal lines may at least include a first control line 110, a second control line 120, a third control line 130, a first test line 210, a second test line 220, and a third test line 230. First ends of the above-described signal lines are correspondingly connected with pins of the bonding pin region, respectively, and second ends of the above-described signal lines extend to the cell test circuit region where the cell test circuit is located, and are correspondingly connected with corresponding test units, respectively.

In an exemplary implementation, the first control line 110 may be connected with control terminals of a plurality of first switching units E1, the first test line 210 may be connected with input terminals of the plurality of first switching units E1, an output terminal of each of the first switching units E1 is connected with the first transmission line 71, and the first switching unit E1 is configured to send a signal transmitted by the first test line 210 to the first data signal line D1 through the first transmission line 71 under control of the first control line 110, so that the data signal line sends the signal to pixel drive circuits of G sub-pixels.

In an exemplary implementation, the second control line 120 may be connected with control terminals of second switching units E2 of odd-numbered test units and control terminals of third switching units E3 of even-numbered test units, respectively, and the third control line 130 may be connected with control terminals of third switching units E3 of the odd-numbered test units and control terminals of second switching units E2 of the even-numbered test units, respectively. The second test line 220 may be connected with input terminals of a plurality of second switching units E2, and the third test line 230 may be connected with input terminals of a plurality of third switching units E3. An output terminal of each second switching unit E2 is connected with the second transmission line 72, and an output terminal of each third switching unit is connected with the second transmission line 72. The second switching unit E2 is configured to send a signal transmitted by the second test line 220 to the second data signal line D2 through the second transmission line 72 under control of the second control line 120 and the third control line 130, so that the data signal line sends the signal to pixel drive circuits of B sub-pixels. The third switching unit E3 is configured to send a signal transmitted by the third test line 230 to the second data signal line D2 through the second transmission line 72 under control of the second control line 120 and the third control line 130, so that the data signal line transmits the signal to pixel drive circuits of R sub-pixels.

In an exemplary implementation, the second control line 120 may be disposed at a side of the first control line 110 away from the display region 100, and the third control line 130 may be disposed at a side of the second control line 120 away from the display region 100.

In an exemplary implementation, the first test line 210 may be disposed at a side of the first control line 110 close to the display region 100, the second test line 220 may be disposed between the first control line 110 and the second control line 120, and the third test line 230 may be disposed at a side of the third control line 130 away from the display region 100.

In an exemplary implementation, a G sub-pixel may be a first sub-pixel of the present disclosure, a B sub-pixel may be a second sub-pixel of the present disclosure, and a R sub-pixel may be a third sub-pixel of the present disclosure.

In an exemplary implementation, an operating process of a CT test performed by a cell test circuit of this exemplary embodiment is as follows:

When a CT test is performed on the G sub-pixels in the display region, the external device causes the first control line 110 to output a first control signal and the first test line 210 to output a lighting voltage signal or an aging voltage signal through the multiple pins. A turned-on signal outputted from the first control line 110 turns on the plurality of first switching units E1, and the lighting voltage signal or the aging voltage signal outputted from the first test line 210 is outputted to first data signal lines D1 connected with the G sub-pixels in the display region through the turned-on first switching units E1, and the CT test is performed on the G sub-pixels in the display region.

When a CT test is performed on the B sub-pixels in the display region, the external device causes the second control line 120 to output a second control signal, the third control line 130 to output a third control signal and the second test line 220 to output a lighting voltage signal or an aging voltage signal through the multiple pins. Turned-on signals outputted by the second control line 120 and the third control line 130 turn on the plurality of second switching units E2, and the lighting voltage signal or the aging voltage signal outputted by the second test line 220 is outputted to second data signal lines D2 connected with the B sub-pixels in the display region through the turned-on second switching units E2, and the CT test is performed on the B sub-pixels in the display region. When a CT test is performed on the R sub-pixels in the display region, the external device causes the second control line 120 to output a second control signal, the third control line 130 to output a third control signal and the second test line 230 to output a lighting voltage signal or an aging voltage signal through the multiple pins. Turned-on signals outputted by the second control line 120 and the third control line 130 turn on the plurality of third switching units E3, and the lighting voltage signal or the aging voltage signal outputted by the second test line 230 is outputted to second data signal lines D2 connected with the R sub-pixels in the display region through the turned-on third switching units E3, and the CT test is performed on the R sub-pixels in the display region.

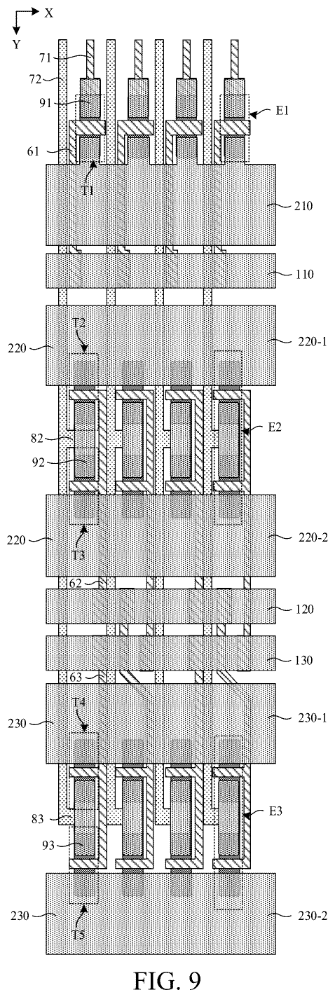

FIG. 9 is a schematic diagram of a structure of a display substrate according to an exemplary embodiment of the present disclosure, illustrating planar structures of four test units in the bonding region. As shown in FIG. 9, the bonding region may at least include a cell test circuit which may at least include a plurality of test units, a plurality of control lines and a plurality of test lines. The plurality of test units may be provided sequentially at set intervals along the first direction X and positions of the plurality of test units may be in one-to-one correspondence with positions of the plurality of data signal lines in the display region. In a region where the cell test circuit is located, the plurality of control lines may be in a shape of a line extending along the first direction X, the plurality of control lines are correspondingly connected with control terminals of the plurality of test units, respectively, the plurality of test lines may be in a shape of a line extending along the first direction X, the plurality of test lines are correspondingly connected with input terminals of the plurality of test units, respectively, and an output terminal of each test unit is connected with a corresponding data signal line through a transmission line.

In an exemplary implementation, the plurality of control lines may at least include a first control line 110, a second control line 120, and a third control line 130. First ends of the first control line 110, the second control line 120, and the third control line 130 are connected with pins of the bonding pin region, respectively. Second ends of the first control line 110, the second control line 120, and the third control line 130, after extending to a region where the cell test circuit is located, are respectively connected with the control terminals of the plurality of test units.

In an exemplary implementation, the plurality of test lines may at least include a first test line 210, a second test line 220, and a third test line 230. First ends of the first test line 210, the second test line 220, and the third test line 230 are respectively connected with pins of the bonding pin region. Second ends of the first test line 210, the second test line 220, and the third test line 230, after extending to the region where the cell test circuit is located, are respectively connected with the input terminals of the plurality of test units.

In an exemplary implementation, at least one test unit may include a first switching unit E1, a second switching unit E2, a third switching unit E3, a first transmission line 71, and a second transmission line 72, the second switching unit E2 may be disposed at a side of the first switching unit E1 away from the display region 100, and the third switching unit E3 may be disposed at a side of the second switching unit E2 away from the display region 100.

In an exemplary implementation, the first switching unit E1 may include at least one first transistor T1, a gate electrode of the first transistor T1 is connected with the first control line 110, a first electrode of the first transistor T1 is connected with the first test line 210, a second electrode of the first transistor T1 is connected with a first end of the first transmission line 71, and a second end of the first transmission line 71 is connected with a data signal line (first data signal line) connected with G sub-pixels in the display region.

In an exemplary implementation, the second switching unit E2 may include at least one second transistor T2 and at least one third transistor T3, and the third switching unit E3 may include at least one fourth transistor T4 and at least one fifth transistor T5. Gate electrodes of second transistors T2 and gate electrodes of third transistors T3 of odd-numbered test units and gate electrodes of fourth transistors T4 and gate electrodes of fifth transistors T5 of even-numbered test units are respectively connected with the second control line 120, and gate electrodes of fourth transistors T4 and gate electrodes of fifth transistors T5 of the odd-numbered test units and gate electrodes of second transistors T2 and gate electrodes of third transistors T3 of the even-numbered test units are respectively connected with the third control line 130. A first electrode of the second transistor T2 and a first electrode of the third transistor T3 of each test unit are respectively connected with the second test line 220, a first electrode of the fourth transistor T4 and a first electrode of the fifth transistor T5 of each test unit are respectively connected with the third test line 230, a second electrode of the second transistor T2, a second electrode of the third transistor T3, a second electrode of the fourth transistor T4 and a second electrode of the fifth transistor T5 of each test unit are respectively connected with a first end of the second transmission line 72, and a second end of the second transmission line 72 is connected with the data signal line (second data signal line) connected with B sub-pixels and the R sub-pixels in the display region.

In an exemplary implementation, the first transmission line 71 may be disposed at a side of the gate electrode of the first transistor T1 is close to the display region, the first test line 210 may be disposed at a side of the gate electrode of the first transistor T1 is away from the display region, and the first control line 110 may be disposed at a side of the first test line 210 is away from the display region.

In an exemplary implementation, the first switching unit E1 may further include a first gate connection line 61, a first end of the first gate connection line 61 is connected with the gate electrode of the first transistor T1, and a second end of the first gate connection line 61, after extending in a direction away from the display region, is connected with the first control line 110 through a via.

In an exemplary implementation, the first switching unit E1 may further include a first connection electrode 91, the first connection electrode 91 may be disposed at a side of the gate electrode of the first transistor T1 close to the display region, a first end of the first connection electrode 91 is connected with an active layer of the first transistor T1 through a via, and a second end of the first connection electrode 92 is connected with the first transmission line 71 through a via.

In an exemplary implementation, the second transistor T2 may be disposed at a side of the first transistor T1 away from the display region, the third transistor T3 may be disposed at a side of the second transistor T2 away from the display region, the fourth transistor T4 may be disposed at a side of the third transistor T3 away from the display region, and the fifth transistor T5 may be disposed at a side of the fourth transistor T4 away from the display region, that is, the first transistor T1, the second transistor T2, the third transistor T3, the fourth transistor T4, and the fifth transistor T5 are sequentially disposed in the direction away from the display region.

In an exemplary implementation, the second test line 220 may include a first sub-line 220-1 and a second sub-line 220-2 which are connected with a same signal source. The first sub-line 220-1 may be disposed at a side of the second transistor T2 close to the display region and connected with first electrodes of a plurality of second transistors T2, respectively. The second sub-lines 220-2 may be disposed at a side of the third transistor T3 away from the display region, and are connected with first electrodes of a plurality of third transistors T3, respectively.

In an exemplary implementation, the first control line 110 may be disposed between the first test line 210 and the first sub-line 220-1, and the second control line 120 may be disposed at a side of the second sub-line 220-2 away from the display region.

In an exemplary implementation, the third test line 230 may include a third sub-line 230-1 and a fourth sub-line 230-2 which are connected with a same signal source. The third sub-line 230-1 may be disposed at a side of the fourth transistor T4 close to the display region and connected with first electrodes of a plurality of fourth transistors T4, respectively. The fourth sub-line 230-2 may be disposed at a side of the fifth transistor T5 away from the display region, and is connected with first electrodes of a plurality of fifth transistors T5, respectively.

In an exemplary implementation, the second control line 120 and the third control line 130 may be disposed between the second sub-line 220-2 and the third sub-line 230-1, and the third control line 130 may be disposed at a side of the second control line 120 away from the display region.

In an exemplary implementation, the second switching unit E2 may further include a second gate connection line 62, a first end of the second gate connection line 62 is connected with a gate electrode of the second transistor T2 and a gate electrode of the third transistor T3, respectively, and a second end of the second gate connection line 62, after extending in the direction away from the display region, is connected with the second control line 120 or the third control line 130 through a via. In an exemplary implementation, second gate connection lines 62 of the odd-numbered test units are connected with the second control line 120, and second gate connection lines 62 of the even-numbered test units are connected with the third control line 130.

In an exemplary implementation, the third switching unit E3 may further include a third gate connection line 63, a first end of the third gate connection line 63 is connected with a gate electrode of the fourth transistor T4 and a gate electrode of the fifth transistor T5, respectively, and a second end of the third gate connection line 63, after extending in the direction close to the display region, is connected with the second control line 120 or the third control line 130 through a via. In an exemplary implementation, third gate connection lines 63 of the odd-numbered test units are connected with the third control line 130, and third gate connection lines 63 of the even-numbered test units are connected with the second control line 120.

In an exemplary implementation, the second switching unit E2 may further include a second connection electrode 92, on the one hand, the second connection electrode 92 is respectively connected with an active layer of the second transistor T2 and an active layer of the third transistor T3 through a via, and on the other hand, the second connection electrode 92 is connected with the second transmission line 72 through a via.

In an exemplary implementation, the third switching unit E3 may further include a third connection electrode 93, on the one hand, the third connection electrode 93 is respectively connected with an active layer of the fourth transistor T4 and an active layer of the fifth transistor T5 through a via, and on the other hand, the third connection electrode 93 is connected with the second transmission line 72 through a via.

In an exemplary implementation, the second switching unit E2 may further include a second connection block 82, the third switching unit E3 may further include a third connection block 83, the second connection block 82 and the third connection block 83 are both connected with the second transmission line 72, the second connection electrode 92 is connected with the second connection block 82 through a via, and the third connection electrode 93 is connected with the third connection block 83 through a via, the second connection block 82, the third connection block 83 and the second transmission line 72 may be disposed in a same layer, are synchronously formed through a same patterning process, and are of an interconnected integral structure.

In an exemplary implementation, on a plane perpendicular to the display substrate, the display substrate may include a semiconductor layer, a first conductive layer, a second conductive layer, and a third conductive layer that are sequentially disposed on the base substrate. The semiconductor layer may at least include active layers of a plurality of transistors, the first conductive layer may at least include the first transmission line 71 and gate electrodes of the plurality of transistors, the second conductive layer may at least include the second transmission line 72, and the third conductive layer may at least include first electrodes and second electrodes of the plurality of transistors.

In an exemplary implementation, the first connection electrode 91, the second connection electrode 92, the third connection electrode 93, the first control line 110, the second control line 120, the third control line 130, the first test line 210, the second test line 220, and the third test line 230 may be disposed in the third conductive layer.

Exemplary description is made below through a preparation process of the cell test circuit. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are arranged in a same layer” in the present disclosure means that A and B are formed simultaneously through a same patterning process, and a “thickness” of a film layer is a dimension of the film layer in a direction perpendicular to a display substrate. In the exemplary embodiments of the present disclosure, “an orthographic projection of A includes an orthographic projection of B” or “an orthographic projection of B is within a range of an orthographic projection of A” means that a boundary of the orthographic projection of B falls within a range of a boundary of the orthographic projection of A, or the boundary of the orthographic projection of A coincides with the boundary of the orthographic projection of B.

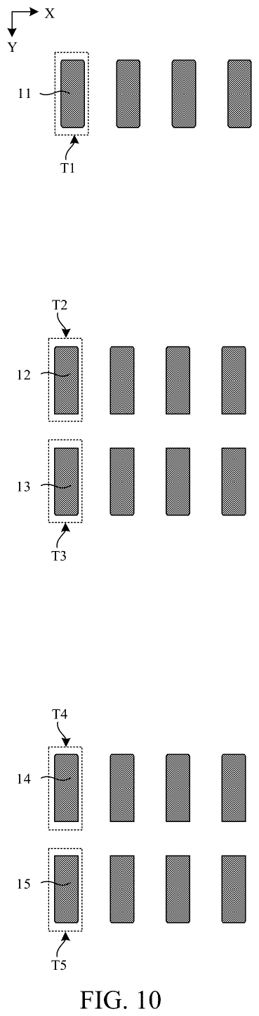

In an exemplary implementation, the preparation process of the cell test circuit may include following operations.
(1) A pattern of a semiconductor layer is formed on a base substrate. In an exemplary implementation, a pattern of a semiconductor layer is formed on a base substrate, which may include: a first insulating thin film and a semiconductor thin film are deposited sequentially on the base substrate, and the semiconductor thin film is patterned through a patterning process to form a first insulating layer that covers the base substrate, and a pattern of a semiconductor layer disposed on the first insulating layer, as shown in FIG. 10.

In an exemplary implementation, the pattern of the semiconductor layer of each test unit may at least include a first active layer 11, a second active layer 12, a third active layer 13, a fourth active layer 14, and a fifth active layer 15 sequentially disposed along the second direction Y, and each active layer may have a shape of a strip extending along the second direction Y.

In an exemplary implementation, the first active layer 11 may be an active layer of a first transistor T1, the second active layer 12 may be an active layer of a second transistor T2, the third active layer 13 may be an active layer of a third transistor T3, the fourth active layer 14 may be an active layer of a fourth transistor T4, the fifth active layer 15 may be an active layer of a fifth transistor T5.

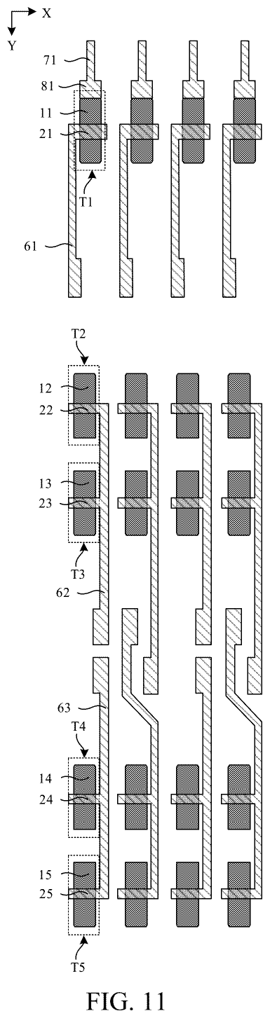

In an exemplary implementation, the patterns of the semiconductor layer of a plurality of test units may be substantially the same.
(2) A pattern of a first conductive layer is formed. In an exemplary implementation, forming the pattern of the first conductive layer may include: a second insulating thin film and a first conductive thin film are sequentially deposited on the base substrate on which the aforementioned patterns are formed, and the first conductive thin film is patterned through a patterning process to form a second insulating layer that covers the pattern of the semiconductor layer, and a pattern of a first conductive layer disposed on the second insulating layer, as shown in FIG. 11. In an exemplary implementation, the first conductive layer may be referred to as a first gate metal (GATE1) layer.

In an exemplary implementation, the pattern of the first conductive layer of each test unit at least includes a plurality of gate electrodes, a plurality of gate connection lines, and a plurality of first transmission lines.

In an exemplary implementation, the plurality of gate electrodes of each test unit may include a first gate electrode 21, a second gate electrode 22, a third gate electrode 23, a fourth gate electrode 24, and a fifth gate electrode 25 sequentially disposed along the second direction Y, each gate electrode may be in a shape of a strip extending along the first direction X, and may be located in a middle region of a corresponding active layer in the second direction Y, and orthographic projections of the plurality of gate electrodes on the base substrate are at least partially overlapped with orthographic projections of a plurality of active layers on the base substrate.

In an exemplary implementation, the first gate electrode 21 may serve as the gate electrode of the first transistor T1, the second gate electrode 22 may serve as the gate electrode of the second transistor T2, the third gate electrode 23 may serve as the gate electrode of the third transistor T3, the fourth gate electrode 24 may serve as the gate electrode of the fourth transistor T4, and the fifth gate electrode 25 may serve as the gate electrode of the fifth transistor T5.

In an exemplary implementation, the plurality of gate connection lines of each test unit may include the first gate connection line 61, the second gate connection line 62, and the third gate connection line 63.

In an exemplary implementation, the first gate connection line 61 may be in a shape of a line with a main body portion extending along the second direction Y, a first end of the first gate connection line 61 close to the display region is connected with the first gate electrode 21, a second end of the first gate connection line 61 extends along the second direction Y in a direction away from the display region, and the first gate connection line 61 is configured to be connected with the first control line formed subsequently.

In an exemplary implementation, the second gate connection line 62 may be in a shape of a line with a main body portion extending along the second direction Y, a first end of the second gate connection line 62 close to the display region is connected with the second gate electrode 22 and the third gate electrode 23, respectively, a second end of the second gate connection line 62 extends along the second direction Y in a direction away from the display region, and the second gate connection line 62 is configured to be connected with the second control line formed subsequently.

In an exemplary implementation, the third gate connection line 63 may be in a shape of a line with a main body portion extending along the second direction Y, a first end of the third gate connection line 63 away from the display region is connected with the fourth gate electrode 24 and the fifth gate electrode 25, respectively, and a second end of the third gate connection line 63 extends along the second direction Y in a direction close to the display region, and the third gate connection line 63 is configured to be connected with the third control line formed subsequently.

In an exemplary implementation, the first transmission line 71 of a test unit may be in a shape of a line with a main body portion extending along the second direction Y, and may be located at a side of the first active layer 11 in an opposite direction of the second direction Y (a side of the first active layer 11 away from the second active layer 12), and the first transmission line 71 is configured to be connected with a data signal line connected to G sub-pixels in the display region.

In an exemplary implementation, the first transmission line 71 may be connected with a first connection block 81 located on a side of the first active layer 11 in an opposite direction of the second direction Y, and the first connection block 81 is configured to be connected with the first active layer 11 by a first connection electrode subsequently formed.

In an exemplary implementation, patterns of the first conductive layer of a plurality of odd-numbered test units may be substantially the same, patterns of the first conductive layer of a plurality of even-numbered test units may be substantially the same, but patterns of the first conductive layer of an odd-numbered test unit and an even-numbered test unit may be different.

In an exemplary implementation, the shapes and positions of the first gate electrodes 21, the first gate connection lines 61, and the first transmission lines 71 in an odd-numbered test unit and an even-numbered test unit are substantially the same.

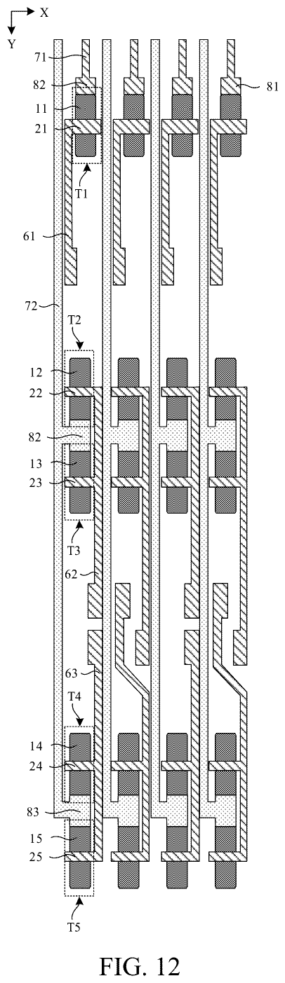

In an exemplary implementation, the shapes and positions of the second gate electrodes 22, the third gate electrodes 23, the fourth gate electrodes 24, and the fifth gate electrodes 25 in an odd-numbered test unit and an even-numbered test unit are substantially the same, and the shapes of the second gate connection lines 62 and the third gate connection lines 63 in an odd-numbered test unit and an even-numbered test unit are different.
(3) A pattern of a second conductive layer is formed. In an exemplary implementation, the operation of forming a pattern of a second conductive layer may include: sequentially depositing a third insulating film and a second conductive film on the base substrate on which the aforementioned pattern is formed, and patterning the second conductive film by a patterning process, to form a third insulating layer covering the pattern of the first conductive layer and a pattern of a second conductive layer provided on the third insulating layer, as shown in FIG. 12. In an exemplary implementation, the second conductive layer may be referred to as a second gate metal (GATE2) layer.

In an exemplary implementation, the pattern of the second conductive layer of each test unit at least includes the second transmission line 72, the second connection block 82 and the third connection block 83.

In an exemplary implementation, the second transmission line 72 of a test unit may be in a shape of a line with a main body portion extending in the second direction Y, may be located at a side of the plurality of active layers in an opposite direction of the first direction X, and the second transmission line 72 is configured to be connected with a data signal line connected to B sub-pixels and R sub-pixels in the display region.

In an exemplary implementation, the second transmission line 72 may be connected with the second connection block 82 and the third connection block 83, respectively, that is, the second connection block 82, the third connection block 83 and the second transmission line 72 may be synchronously formed through a same patterning process, and are of an interconnected integral structure. The second connection block 82 may be disposed between the second active layer 12 and the third active layer 13, and the second connection block 82 is configured to be connected with the second active layer 12 and the third active layer 13, respectively, through a second connection electrode subsequently formed. The third connection block 83 may be disposed between the fourth active layer 14 and the fifth active layer 15, and the third connection block 83 is configured to be connected with the fourth active layer 14 and the fifth active layer 15, respectively, through a third connection electrode subsequently formed.

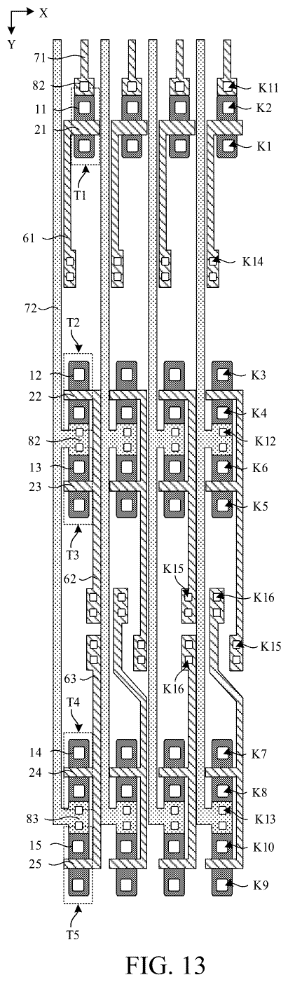

In an exemplary implementation, patterns of the second conductive layers of the plurality of test units may be substantially the same.
(4) A pattern of a fourth insulating layer is formed. In an exemplary implementation, forming a pattern of a fourth insulating layer may include depositing a fourth insulating thin film the base substrate on which the aforementioned pattern is formed, patterning the fourth insulating thin film by a patterning process, forming a pattern of a fourth insulating layer covering the second conductive layer, and a plurality of vias are formed on the fourth insulating layer, as shown in FIG. 13.

In an exemplary implementation, the plurality of vias of each test unit include: a first via K1, a second via K2, a third via K3, a fourth via K4, a fifth via K5, a sixth via K6, a seventh via K7, an eighth via K8, a ninth via K9, a tenth via K10, an eleventh via K11, a twelfth via K12, a thirteenth via K13, a fourteenth via K14, a fifteenth via K15, a sixteenth via K16.

In an exemplary implementation, an orthographic projection of the first via K1 on the base substrate may be located within a range of an orthographic projection of a first region of the first active layer 11 on the base substrate. The second insulating layer, the third insulating layer, and the fourth insulating layer in the first via K1 are etched away to expose a surface of the first region of the first active layer 11, and the first via K1 is configured such that the first test line formed subsequently is connected to the first region of the first active layer 11 through the via.

In an exemplary implementation, an orthographic projection of the second via K2 on the base substrate may be located within a range of an orthographic projection of a second region of the first active layer 11 on the base substrate. The second insulating layer, the third insulating layer, and the fourth insulating layer within the second via K2 are etched away to expose a surface of the second region of the first active layer 11, and the second via K2 is configured such that the first connection electrode formed subsequently is connected to the second region of the first active layer 11 through the via.

In an exemplary implementation, an orthographic projection of the third via K3 on the base substrate may be located within a range of an orthographic projection of a first region of the second active layer 12 on the base substrate. The second insulating layer, the third insulating layer, and the fourth insulating layer within the third via K3 are etched away to expose a surface of the first region of the second active layer 12, and the third via K3 is configured such that the second test line formed subsequently is connected to the first region of the second active layer 12 through the via.

In an exemplary implementation, an orthographic projection of the fourth via K4 on the base substrate may be located within a range of an orthographic projection of a second region of the second active layer 12 on the base substrate. The second insulating layer, the third insulating layer, and the fourth insulating layer within the fourth via K4 are etched away to expose a surface of the second region of the second active layer 12, and the fourth via K4 is configured such that the second connection electrode formed subsequently is connected to the second region of the second active layer 12 through the via.

In an exemplary implementation, an orthographic projection of the fifth via K5 on the base substrate may be located within a range of an orthographic projection of a first region of the third active layer 13 on the base substrate. The second insulating layer, the third insulating layer, and the fourth insulating layer within the fifth via K5 are etched away to expose a surface of the first region of the third active layer 13, and the fifth via K5 is configured such that the second test line formed subsequently is connected to the first region of the third active layer 13 through the via.

In an exemplary implementation, an orthographic projection of the sixth via K6 on the base substrate may be located within a range of an orthographic projection of a second region of the third active layer 13 on the base substrate. The second insulating layer, the third insulating layer and the fourth insulating layer within the sixth via K6 are etched away to expose a surface of the second region of the third active layer 13, and the sixth via K6 is configured such that the second connection electrode formed subsequently is connected to the second region of the third active layer 13 through the via.

In an exemplary implementation, an orthographic projection of the seventh via K7 on the base substrate may be located within a range of an orthographic projection of a first region of the fourth active layer 14 on the base substrate. The second insulating layer, the third insulating layer, and the fourth insulating layer within the seventh via K7 are etched away to expose a surface of the first region of the fourth active layer 14, and the seventh via K7 is configured such that the third test line formed subsequently is connected to the first region of the fourth active layer 14 through the via.

In an exemplary implementation, an orthographic projection of the eighth via K8 on the base substrate may be located within a range of an orthographic projection of a second region of the fourth active layer 14 on the base substrate. The second insulating layer, the third insulating layer, and the fourth insulating layer within the eighth via K8 are etched away to expose a surface of the second region of the fourth active layer 14, and the eighth via K8 is configured such that the third connection electrode formed subsequently is connected to the second region of the fourth active layer 14 through the via.

In an exemplary implementation, an orthographic projection of the ninth via K9 on the base substrate may be located within a range of an orthographic projection of a first region of the fifth active layer 15 on the base substrate. The second insulating layer, the third insulating layer, and the fourth insulating layer within the ninth via K9 are etched away to expose a surface of the first region of the fifth active layer 15, and the ninth via K9 is configured such that the third test line formed subsequently is connected to the first region of the fifth active layer 15 through the via.

In an exemplary implementation, an orthographic projection of the tenth via K10 on the base substrate may be located within a range of an orthographic projection of a second region of the fifth active layer 15 on the base substrate. The second insulating layer, the third insulating layer, and the fourth insulating layer within the tenth via K10 are etched away to expose a surface of the second region of the fifth active layer 15, and the tenth via K10 is configured such that the third connection electrode formed subsequently is connected to the second region of the fifth active layer 15 through the via.

In an exemplary implementation, an orthographic projection of the eleventh via K11 on the base substrate may be located within a range of an orthographic projection of the first connection block 81 of the first transmission line 71 on the base substrate. The third and fourth insulating layers within the eleventh via K11 are etched away to expose a surface of the first connection block 81, and the eleventh via K11 is configured such that the first connection electrode formed subsequently is connected to the first connection block 81 through the via.

In an exemplary implementation, an orthographic projection of the twelfth via K12 on the base substrate may be located within a range of an orthographic projection of the second connection block 82 of the second transmission line 72 on the base substrate. The fourth insulating layer within the twelfth via K12 is etched away to expose a surface of the second connection block 82, and the twelfth via K12 is configured such that the second connection electrode formed subsequently is connected to the second connection block 82 through the via. In an exemplary implementation, the twelfth via K12 may be multiple to increase connection reliability.

In an exemplary implementation, an orthographic projection of the thirteenth via K13 on the base substrate may be located within a range of an orthographic projection of the third connection block 83 of the second transmission line 72 on the base substrate. The fourth insulating layer within the thirteenth via K13 is etched away to expose a surface of the third connection block 83, and the thirteenth via K13 is configured such that the third connection electrode formed subsequently is connected to the third connection block 83 through the via. In an exemplary implementation, the thirteenth via K13 may be multiple to increase connection reliability.

In an exemplary implementation, an orthographic projection of the fourteenth via K14 on the base substrate may be located within a range of an orthographic projection of the first gate connection line 61 on the base substrate. The third and fourth insulating layers within the fourteenth via K14 are etched away to expose a surface of the second end of the first gate connection line 61, and the fourteenth via K14 is configured such that the first control line formed subsequently is connected to the first gate connection line 61 through the via. In an exemplary implementation, the fourteenth via K14 may be multiple to increase connection reliability.

In an exemplary implementation, an orthographic projection of the fifteenth via K15 on the base substrate may be located within a range of an orthographic projection of the second gate connection line 62 on the base substrate. The third insulating layer and the fourth insulating layer within the fifteenth via K15 are etched away to expose a surface of the second end of the second gate connection line 62. The fifteenth via K15 in an odd-numbered test unit is configured such that the second control line formed subsequently is connected to the second gate connection line 62 through the via. The fifteenth via K15 in an even-numbered test unit is configured such that the third control line formed subsequently is connected to the second gate connection line 62 through the via. In an exemplary implementation, the fifteenth via K15 may be multiple to increase connection reliability.

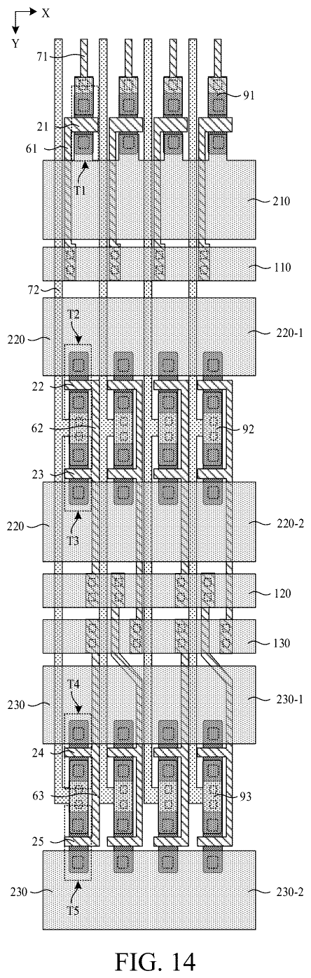

In an exemplary implementation, an orthographic projection of the sixteenth via K16 on the base substrate may be located within a range of an orthographic projection of the third gate connection line 63 on the base substrate. The third insulating layer and the fourth insulating layer within the sixteenth via K16 are etched away to expose a surface of the second end of the third gate connection line 63, the sixteenth via K16 in an odd-numbered test unit is configured such that the third control line formed subsequently is connected to the third gate connection line 63 through the via, and the sixteenth via K16 in an even-numbered test unit is configured such that the second control line formed subsequently is connected to the third gate connection line 63 through the via. In an exemplary implementation, the sixteenth via K16 may be multiple to increase connection reliability.
(4) A pattern of a third conductive layer is formed. In an exemplary implementation, forming a pattern of a third conductive layer may include depositing a third conductive thin film on the base substrate on which the aforementioned pattern is formed, and patterning the third conductive thin film by a patterning process, to form a pattern of a third conductive layer on the fourth insulating layer, as shown in FIG. 14. In an exemplary implementation, the third conductive layer may be referred to as a first source drain metal layer (SD1).

In an exemplary implementation, the pattern of the third conductive layer may include the first control line 110, the second control line 120, the third control line 130, the first test line 210, the second test line 220, the third test line 230, the first connection electrode 91, the second connection electrode 92, and the third connection electrode 93.

In an exemplary implementation, the first control line 110 may have a shape of a line extending along the first direction X. A first end of the first control line 110 is connected with a pin of the bonding pin region, and a second end of the first control line 110 extends to the cell test circuit region, and is connected with the first gate connection line 61 in each test unit through a plurality of fourteenth vias K14. Since the first gate connection line 61 is connected with the first gate electrode 21, a first control signal transmitted by the first control line 110 can be transmitted to the first gate electrode 21 through the first gate connection line 61, respectively, to control on and off of the first transistor T1.

In an exemplary implementation, the second control line 120 may be in a shape of a line extending in the first direction X. A first end of the second control line 120 is connected with a pin of the bonding pin region, and a second end of the second control line 120 extends to the cell test circuit region and is connected with the second gate connection line 62 through the fifteenth via K15 in odd-numbered test units on the one hand, and is connected with the third gate connection line 63 through the sixteenth via K16 in even-numbered test units on the other hand. Since the second gate connection line 62 is connected with the second gate electrode 22 and the third gate electrode 23, a second control signal transmitted by the second control line 120 can control on and off of second transistors T2 and third transistors T3 in the odd-numbered test units. Since the third gate connection line 63 is connected with the fourth gate electrode 24 and the fifth gate electrode 25, a second control signal transmitted by the second control line 120 can control on and off of fourth transistors T4 and fifth transistors T5 in the even-numbered test units.

In an exemplary implementation, the third control line 130 may be in a shape of a line extending in the first direction X. A first end of the third control line 130 is connected with a pin of the bonding pin region, and a second end of the third control line 130 extends to the cell test circuit region and is connected with the third gate connection line 63 through the sixteenth via K16 in the odd-numbered test units on the one hand, and is connected with the second gate connection line 62 through the fifteenth via K15 in the even-numbered test units on the other hand. Since the second gate connection line 62 is connected with the second gate electrode 22 and the third gate electrode 23, a third control signal transmitted by the third control line 130 can control on and off of second transistors T2 and third transistors T3 in the even-numbered test units. Since the third gate connection line 63 is connected with the fourth gate electrode 24 and the fifth gate electrode 25, a third control signal transmitted by the third control line 130 can control the on and off of fourth transistors T4 and fifth transistors T5 in the odd-numbered test units.

In an exemplary implementation, the first test line 210 may be in a shape of a line extending in the first direction X, a first end of the first test line 210 is connected with a pin of the bonding pin region, and a second end of the first test line 210, after extending to the cell test circuit region, is connected with the first region of the first active layer 11 in each test unit through the first via K1.

In an exemplary implementation, the second test line 220 may include a first sub-line 220-1 and a second sub-line 220-2 which are connected with a same signal source. The first sub-line 220-1 may be in a shape of a line extending in the first direction X. A first end of the first sub-line 220-1 is connected with a pin of the bonding pin region. A second end of the first sub-line 220-1, after extending to the cell test circuit region, is connected with the first region of the second active layer 12 in each test unit through the third via K3. The second sub-line 220-2 may be in a shape of a line extending in the first direction X. A first end of the second sub-line 220-2 is connected with a pin of the bonding pin region. A second end of the second sub-line 220-2, after extending to the cell test circuit region, is connected with the first region of the third active layer 13 in each test unit through the fifth via K5.

In an exemplary implementation, the third test line 230 may include a third sub-line 230-1 and a fourth sub-line 230-2 which are connected with a same signal source. The third sub-line 230-1 may be in a shape of a line extending in the first direction X. A first end of the third sub-line 230-1 is connected with a pin of the bonding pin region. A second end of the third sub-line 230-1, after extending to the cell test circuit region, is connected with the first region of the fourth active layer 14 in each test unit through the seventh via K7. The fourth sub-line 230-2 may be in a shape of a line extending in the first direction X, a first end of the fourth sub-line 230-2 is connected with a pin of the bonding pin region, and a second end of the fourth sub-line 230-2, after extending to the cell test circuit region, is connected with the first region of the fifth active layer 15 in each test unit through the ninth via K9.

In an exemplary implementation, the first connection electrode 91 may be disposed at a side of the first gate electrode 21 of each test unit in an opposite direction of the second direction Y (a side of the first gate electrode 21 away from the second gate electrode 22), and the first connection electrode 91 may be in a shape of a strip extending along the second direction Y. A first end of the first connection electrode 91 is connected with the second region of the first active layer 11 through the second via K2, and a second end of the first connection electrode 91 is connected with the first connection block 81 of the first transmission line 71 through the eleventh via K11, realizing that the first transistor T1 can control the conduction and disconnection between the first test line 210 and the first transmission line 71. When the first transistor T1 is turned on, a first signal transmitted by the first test line 210 is transmitted to the first transmission line 71, and the first transmission line 71 transmits the first signal to a data signal line connected to G sub-pixels in the display region.

In an exemplary implementation, the second connection electrode 92 may be disposed between the second gate electrode 22 and the third gate electrode 23 of each test unit, and the second connection electrode 92 may be in a shape of a strip extending in the second direction Y. A first end of the second connection electrode 92 is connected with the second region of the second active layer 12 through the fourth via K4, a second end of the second connection electrode 92 is connected with the second region of the third active layer 13 through the sixth via K6, and a middle part (between the first end and the second end) of the second connection electrode 92 is connected with the second connection block 82 of the second transmission line 72 through a plurality of twelfth vias K12, realizing that the second transistors T2 and T3 can control the conduction and disconnection between the first sub-line 220-1 and the second sub-line 220-2 and the second transmission line 72. When the second transistor T2 and the third transistor T3 are turned on, a second signal transmitted by the first sub-line 220-1 and the second sub-line 220-2 is transmitted to the second transmission line 72, and the second transmission line 72 transmits the second signal to a data signal line connected to B sub-pixels and R sub-pixels in the display region.

In an exemplary implementation, the third connection electrode 93 may be disposed between the fourth gate electrode 24 and the fifth gate electrode 25 of each test unit, and the third connection electrode 93 may be in a shape of a strip extending in the second direction Y. A first end of the third connection electrode 93 is connected with the second region of the fourth active layer 14 through the eighth via K8, a second end of the third connection electrode 93 is connected with the second region of the fifth active layer 15 through the tenth via K10, and a middle part (between the first end and the second end) of the third connection electrode 93 is connected with the third connection block 83 of the second transmission line 72 through a plurality of thirteenth vias K13, realizing that the fourth transistors T4 and T5 can control the conduction and disconnection between the third sub-line 230-1 and the fourth sub-line 230-2 and the second transmission line 72. When the fourth transistor T4 and the fifth transistor T5 are turned on, a third signal transmitted by the third sub-line 230-1 and the fourth sub-line 230-2 is transmitted to the second transmission line 72, and the second transmission line 72 transmits the third signal to a data signal line connected to B sub-pixels and R sub-pixels in the display region.

In an exemplary implementation, the first test line 210 may be disposed at a side of the first transistor T1 in the second direction Y (away from the display region). The first sub-line 220-1 may be disposed at a side of the second transistor T2 in an opposite direction of the second direction Y (close to the display region), and the second sub-line 220-2 may be disposed at a side of the third transistor T3 in the second direction Y. The third sub-line 230-1 may be disposed at a side of the fourth transistor T4 in an opposite direction of the second direction Y, and the fourth sub-line 230-2 may be disposed at a side of the fifth transistor T5 in the second direction Y.

In an exemplary implementation, the first control line 110 may be disposed between the first test line 210 and the first sub-line 220-1, the second control line 120 and the third control line 130 may be disposed between the second sub-line 220-2 and the third sub-line 230-1, and the third control line 130 may be disposed at a side of the second control line 120 in the second direction Y.

So far, preparation of a cell test circuit is completed. The cell test circuit may include a plurality of test units sequentially disposed along the first direction X, and at least one test unit may include a first transistor T1, a second transistor T2, a third transistor T3, a fourth transistor T4, and a fifth transistor T5. A gate electrode of the first transistor T1 is connected with the first control line 110, a first electrode of the first transistor T1 is connected with the first test line 210, and a second electrode of the first transistor T1 is connected with the first transmission line 71. Gate electrodes of the second and third transistors T2 and T3 are connected with the second control line 120, first electrodes of the second and third transistors T2 and T3 are connected with the second test line 220, and second electrodes of the second and third transistors T2 and T3 are connected with the second transmission line 72. Gate electrodes of the fourth and fifth transistors T4 and T5 are connected with the third control line 130, first electrodes of the fourth and fifth transistors T4 and T5 are connected with the third test line 230, and second electrodes of the fourth and fifth transistors T4 and T5 are connected with the second transmission line 72.

In an exemplary implementation, the base substrate may be a flexible base substrate, or a rigid base substrate. The flexible base substrate may include a first flexible material layer, a first inorganic material layer, a semiconductor layer, a second flexible material layer and a second inorganic material layer which are stacked. Materials of the first flexible material layer and the second flexible material layer may be Polyimide (PI), Polyethylene Terephthalate (PET) or a polymer soft film with surface treatment. Materials of the first inorganic material layer and the second inorganic material layer may be Silicon Nitride (SiNx) or Silicon Oxide (SiOx), for improving water and oxygen resistance of the base substrate, and a material of the semiconductor layer may be amorphous silicon (a-si).

In an exemplary implementation, the first insulating layer, the second insulating layer, the third insulating layer, and the fourth insulating layer may be made of any one or more of Silicon Oxide (SiOx), Silicon Nitride (SiNx), and Silicon Oxynitride (SiON), and may be a single layer, a multi-layer, or a composite layer. The first insulating layer may be referred to as a buffer layer and used for improving a water and oxygen resistance capability of the base substrate. The second insulating layer and the third insulating layer may be referred to as Gate Insulation (GI) layers. The fourth insulating layer may be referred to as an Interlayer Dielectric (ILD) layer. The first conductive layer, the second conductive layer, and the third conductive layer may be made of a metal material, for example, any one or more of Argentum (Ag), Copper (Cu), Aluminum (Al), Titanium (Ti), and Molybdenum (Mo), or an alloy material of the abovementioned metals, for example, an Aluminum-Neodymium alloy (AlNd) or a Molybdenum-Niobium alloy (MoNb), and may be of a single-layer structure, or a multilayer composite structure such as Ti/Al/Ti. The active layer thin film may be made of materials, such as amorphous Indium Gallium Zinc Oxide (a-IGZO), Zinc Oxynitride (ZnON), Indium Zinc Tin Oxide (IZTO), amorphous Silicon (a-Si), polycrystalline Silicon (p-Si), hexathiophene, and polythiophene. Namely, the present disclosure is applicable to transistors prepared based on an oxide technology, a silicon technology, and an organic matter technology.

As can be seen from the structure and the preparation process of the display substrate according to the present exemplary embodiment, the present disclosure effectively reduces the size of the test unit by providing the first switch unit for controlling the test on G sub-pixels at a side close to the display region. Compared with the existing solution in which the first switching unit for controlling the test on the G sub-pixels is disposed at a side away from the display region, the present disclosure, by providing the first switching unit for controlling the test on the G sub-pixels at a side close to the display region, not only makes it possible to provide only a second transmission line connected to data signal lines in the R sub-pixels and the B sub-pixels in the second switching unit for controlling the test on R sub-pixels and the third switching unit for controlling the test on B sub-pixels, and no longer provide a first transmission line connected to the data signal line in the G sub-pixels, thereby effectively reducing the width of the test unit, but also avoids the signal interference between the first transmission line and the second transmission line, thereby improving the test quality. Without increasing the patterning process, the width of the test unit according to the exemplary embodiment of the present disclosure can be reduced by about 20%, and can be reduced from about 53 μm of the existing structure to about 42 μm, which effectively reduces the size of the test unit and is conducive to realizing a narrowing design of the bonding region. The preparation process of the present disclosure may be achieved by using mature preparation equipment, with little process improvement, high compatibility, simple process realization, easy implementation, high production efficiency, low production cost, and high yield rate, and therefore has a good application prospect.

An exemplary embodiment of the present disclosure further provides a preparation method of a display substrate for preparing the aforementioned display substrate. In an exemplary implementation, the display substrate includes a display region and a bonding region located on a side of the display region, wherein the display region at least includes a plurality of sub-pixels constituting a plurality of pixel columns and a plurality of data signal lines, and the bonding region at least includes a cell test circuit; the plurality of pixel columns at least include a first pixel column and a second pixel column, the first pixel column includes a plurality of first sub-pixels emitting light of a first color, and the second pixel column includes a plurality of second sub-pixels emitting light of a second color and a plurality of third sub-pixels emitting light of a third color; the plurality of data signal lines at least include a first data signal line and a second data signal line, the first data signal line is electrically connected with the plurality of first sub-pixels in the first pixel column, and the second data signal line is electrically connected with the plurality of second sub-pixels and the plurality of third sub-pixels in the second pixel column; the preparation method may include: forming the cell test circuit in the bonding region, the cell test circuit includes a plurality of test units, at least one test unit includes a first switching unit, a second switching unit, a third switching unit, a first transmission line and a second transmission line, wherein the first switching unit is connected with the first data signal line through the first transmission line, the second switching unit and the third switching unit are connected with the second data signal line through the second transmission line, and the second switching unit and the third switching unit are disposed at a side of the first switching unit away from the display region.

An exemplary embodiment of the present disclosure also provides a display apparatus, which includes the display substrate of the foregoing embodiments. The display apparatus may be any product or component with a display function, such as a mobile phone, a tablet computer, a television, a display, a laptop computer, a digital photo frame, or a navigator.

Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display substrate, comprising a display region and a bonding region located on a side of the display region, wherein the display region at least comprises a plurality of sub-pixels constituting a plurality of pixel columns and a plurality of data signal lines, and the bonding region at least comprises a cell test circuit; the plurality of pixel columns at least comprise a first pixel column and a second pixel column, the first pixel column comprises a plurality of first sub-pixels emitting light of a first color, and the second pixel column comprises a plurality of second sub-pixels emitting light of a second color and a plurality of third sub-pixels emitting light of a third color; the plurality of data signal lines at least comprise a first data signal line and a second data signal line, the first data signal line is electrically connected with the plurality of first sub-pixels in the first pixel column, and the second data signal line is electrically connected with the plurality of second sub-pixels and the plurality of third sub-pixels in the second pixel column; the cell test circuit comprises a plurality of test units, at least one test unit comprises a first switching unit, a second switching unit, a third switching unit, a first transmission line, and a second transmission line, wherein the first switching unit is connected with the first data signal line through the first transmission line, and the second switching unit and the third switching unit are connected with the second data signal line through the second transmission line; the second switching unit and the third switching unit are disposed at a side of the first switching unit away from the display region.

2. The display substrate according to claim 1, wherein an extension length of the first transmission line is less than an extension length of the second transmission line in the bonding region.

3. The display substrate according to claim 1, wherein one of the plurality of first sub-pixels comprises a green sub-pixel emitting green light, one of the plurality of second sub-pixels comprises a blue sub-pixel emitting blue light, and one of the plurality of third sub-pixels comprises a red sub-pixel emitting red light.

4. The display substrate according to claim 1, wherein the cell test circuit further comprises a first control line and a first test line; the first control line is connected with a control terminal of the first switching unit, the first test line is connected with an input terminal of the first switching unit, an output terminal of the first switching unit is connected with the first transmission line, and the first switching unit is configured to send a signal transmitted by the first test line to the first data signal line through the first transmission line under control of the first control line.

5. The display substrate according to claim 4, wherein the first switching unit comprises at least one first transistor, the first control line is connected with a gate electrode of the first transistor, the first test line is connected with a first electrode of the first transistor, and a second electrode of the first transistor is connected with the first transmission line.

6. The display substrate according to claim 5, wherein the first transmission line is disposed at a side of the gate electrode of the first transistor close to the display region, the first test line is disposed at a side of the gate electrode of the first transistor away from the display region, and the first control line is disposed at a side of the first test line away from the display region.

7. The display substrate according to claim 5, wherein the first switching unit further comprises a first gate connection line, a first end of the first gate connection line is connected with the gate electrode of the first transistor, and a second end of the first gate connection line, after extending along a direction away from the display region, is connected with the first control line through a via;
or,
the first switching unit further comprises a first connection electrode, a first end of the first connection electrode is connected with the first electrode of the first transistor through a via, and a second end of the first connection electrode is connected with the first transmission line through a via.

8. (canceled)

9. The display substrate according to claim 1, wherein the cell test circuit further comprises a second control line, a third control line, a second test line, and a third test line; the second control line is respectively connected with control terminals of second switching units in odd-numbered test units and control terminals of third switching units in even-numbered test units, and the third control line is respectively connected with control terminals of third switching units in the odd-numbered test units and control terminals of second switching units in the even-numbered test units; the second test line is connected with an input terminal of the second switching unit, and the third test line is connected with an input terminal of the third switching unit; an output terminal of the second switching unit is connected with the second transmission line, and an output terminal of the third switching unit is connected with the second transmission line; the second switching unit is configured to transmit a signal transmitted by the second test line to the second data signal line through the second transmission line under control of the second control line and the third control line, and the third switching unit is configured to transmit a signal transmitted by the third test line to the second data signal line through the second transmission line under control of the second control line and the third control line.

10. The display substrate according to claim 9, wherein the second switching unit comprises at least one second transistor and at least one third transistor, and the third switching unit comprises at least one fourth transistor and at least one fifth transistor; the second control line is connected with gate electrodes of second transistors and gate electrodes of third transistors in the odd-numbered test units, and gate electrodes of fourth transistors and gate electrodes of fifth transistors in the even-numbered test units, respectively; the third control line is connected with gate electrodes of fourth transistors and gate electrodes of fifth transistors in the odd-numbered test units, and gate electrodes of second transistors and gate electrodes of third transistors in the even-numbered test units, respectively; the second test line is connected with a first electrode of the second transistor and a first electrode of the third transistor, respectively, and the third test line is connected with a first electrode of the fourth transistor and a first electrode of the fifth transistor, respectively; and a second electrode of the second transistor, a second electrode of the third transistor, a second electrode of the fourth transistor, and a second electrode of the fifth transistor are connected with the second transmission line.

11. The display substrate according to claim 10, wherein the third transistor is disposed at a side of the second transistor away from the display region, the fourth transistor is disposed at a side of the third transistor away from the display region, and the fifth transistor is disposed at a side of the fourth transistor away from the display region.

12. The display substrate according to claim 10, wherein the second test line comprises a first sub-line and a second sub-line; the first sub-line is disposed at a side of the second transistor close to the display region, and is connected with the first electrode of the second transistor; the second sub-line is disposed at a side of the third transistor away from the display region and is connected with the first electrode of the third transistor; and the second control line is disposed at a side of the second sub-line away from the display region.

13. The display substrate according to claim 10, wherein the second switching unit further comprises a second gate connection line, a first end of the second gate connection line is connected with a gate electrode of the second transistor and a gate electrode of the third transistor, respectively, and a second end of the second gate connection line, after extending along a direction away from the display region, is connected with the second control line or the third control line through a via.

14. The display substrate according to claim 10, wherein the second switching unit further comprises a second connection electrode, and the second connection electrode is respectively connected with the second electrode of the second transistor, the second electrode of the third transistor, and the second transmission line through a via.

15. The display substrate according to claim 14, wherein the second switching unit further comprises a second connection block, the second connection block is connected with the second transmission line, the second connection electrode is connected with the second connection block through a via, and the second connection block and the second transmission line are disposed in a same layer and are of an interconnected integral structure.

16. The display substrate according to claim 10, wherein the third test line comprises a third sub-line and a fourth sub-line; the third sub-line is disposed at a side of the fourth transistor close to the display region, and is connected with the first electrode of the fourth transistor; the fourth sub-line is disposed at a side of the fifth transistor away from the display region and is connected with the first electrode of the fifth transistor; and the third control line is disposed at a side of the third sub-line close to the display region.

17. The display substrate according to claim 16, wherein the third switching unit further comprises a third gate connection line, a first end of the third gate connection line is connected with a gate electrode of the fourth transistor and a gate electrode of the fifth transistor, respectively, and a second end of the third gate connection line, after extending along a direction close to the display region, is connected with the second control line or the third control line through a via.

18. The display substrate according to claim 16, wherein the third switching unit further comprises a third connection electrode, and the third connection electrode is respectively connected with the second electrode of the fourth transistor, the second electrode of the fifth transistor, and the second transmission line through a via.

19. The display substrate according to claim 18, wherein the third switching unit further comprises a third connection block, the third connection block is connected with the second transmission line, the third connection electrode is connected with the third connection block through a via, and the third connection block and the second transmission line are disposed in a same layer and are of an interconnected integral structure.

20. A display apparatus, comprising a display substrate according to claim 1.

21. A preparation method of a display substrate, wherein the display substrate comprises a display region and a bonding region located on a side of the display region, wherein the display region at least comprises a plurality of sub-pixels constituting a plurality of pixel columns and a plurality of data signal lines, and the bonding region at least comprises a cell test circuit; the plurality of pixel columns at least comprise a first pixel column and a second pixel column, the first pixel column comprises a plurality of first sub-pixels emitting light of a first color, and the second pixel column comprises a plurality of second sub-pixels emitting light of a second color and a plurality of third sub-pixels emitting light of a third color; the plurality of data signal lines at least comprise a first data signal line and a second data signal line, the first data signal line is electrically connected with the plurality of first sub-pixels in the first pixel column, and the second data signal line is electrically connected with the plurality of second sub-pixels and the plurality of third sub-pixels in the second pixel column; the preparation method comprises:
forming the cell test circuit in the bonding region, wherein the cell test circuit comprises a plurality of test units, at least one test unit comprises a first switching unit, a second switching unit, a third switching unit, a first transmission line, and a second transmission line, the first switching unit is connected with the first data signal line through the first transmission line, the second switching unit and the third switching unit are connected with the second data signal line through the second transmission line, and the second switching unit and the third switching unit are disposed at a side of the first switching unit away from the display region.
